(19) United States
(12) Patent Application Publication
(10) Pub. No.: US 2026/0128813 A1
(43) Pub. Date: May 7, 2026

(54) PROBABILISTIC SHAPING BASED ON BLOCK CODES

(71) Applicant: QUALCOMM Incorporated, San Diego, CA (US)

(72) Inventors: Wei YANG, San Diego, CA (US); Jing JIANG, San Diego, CA (US); Liangming WU, Beijing (CN)

(21) Appl. No.: 19/120,655

(22) PCT Filed: Dec. 21, 2022
(86) PCT No.: PCT/CN2022/140573

§ 371 Date: Apr. 11, 2025

(51) Int. Cl. H04L 1/00; H03M 13/13

(52) U.S. Cl. CPC H04L 1/0042; H03M 13/13; H04L 1/0057

(57) ABSTRACT

Methods, systems, and devices for wireless communications are described. A transmitting device may support shaping of bits in block encoding schemes and a probabilistic shaping framework to generate shaped bits that include both information bits and shaping bits, without conveying extra information (e.g., in addition to the shaped bits) to a receiving device. The transmitter may use a decoder such as a polar decoder (e.g., a modem configured for both coding and decoding) to determine a set of shaping bits based on the information bits. The transmitting deice may also map information bits to frozen bit locations of the polar code, and the shaping bits to information bit locations of the polar, such that the encoded (e. g., shaped) bits from the polar encoder satisfy a target probability distribution.

### CROSS REFERENCE

The present application is a 371 national phase filing of International PCT Application No. PCT/CN2022/140573 by YANG et al., entitled “PROBABILISTIC SHAPING BASED ON BLOCK CODES,” filed Dec. 21, 2022, which is assigned to the assignee hereof, and which is expressly incorporated by reference in its entirety herein.

### INTRODUCTION

The following relates to wireless communications, including probabilistic shaping according to various encoding schemes.

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The described techniques relate to improved methods, systems, devices, and apparatuses that support probabilistic shaping based on block codes.

A method for wireless communications at a first device is described. The method may include generating, based on a set of multiple information bits, a set of multiple shaping bits associated with shaping the set of multiple information bits into a target probability distribution associated with a block encoding scheme, encoding the set of multiple information bits and the set of multiple shaping bits according to the block encoding scheme to generate a set of multiple shaped bits satisfying the target probability distribution, and outputting a message that is based on the set of multiple shaped bits.

An apparatus for wireless communications at a first device is described. The apparatus may include a processor, memory coupled with the processor, and instructions stored in the memory. The instructions may be executable by the processor to cause the apparatus to generate, based on a set of multiple information bits, a set of multiple shaping bits associated with shaping the set of multiple information bits into a target probability distribution associated with a block encoding scheme, encode the set of multiple information bits and the set of multiple shaping bits according to the block encoding scheme to generate a set of multiple shaped bits satisfying the target probability distribution, and output a message that is based on the set of multiple shaped bits.

Another apparatus for wireless communications at a first device is described. The apparatus may include means for generating, based on a set of multiple information bits, a set of multiple shaping bits associated with shaping the set of multiple information bits into a target probability distribution associated with a block encoding scheme, means for encoding the set of multiple information bits and the set of multiple shaping bits according to the block encoding scheme to generate a set of multiple shaped bits satisfying the target probability distribution, and means for outputting a message that is based on the set of multiple shaped bits.

A non-transitory computer-readable medium storing code for wireless communications at a first device is described. The code may include instructions executable by a processor to generate, based on a set of multiple information bits, a set of multiple shaping bits associated with shaping the set of multiple information bits into a target probability distribution associated with a block encoding scheme, encode the set of multiple information bits and the set of multiple shaping bits according to the block encoding scheme to generate a set of multiple shaped bits satisfying the target probability distribution, and output a message that is based on the set of multiple shaped bits.

Some examples of the method, apparatuses, and non-transitory computer-readable medium described herein may further include operations, features, means, or instructions for determining the block encoding scheme associated with the target probability distribution for transmission of the message.

In some examples of the method, apparatuses, and non-transitory computer-readable medium described herein, communicating, with a second device, control signaling scheduling a transmission of the message and indicating the block encoding scheme, where determining the block encoding scheme may be based on communicating the control signaling.

Some examples of the method, apparatuses, and non-transitory computer-readable medium described herein may further include operations, features, means, or instructions for communicating the control signaling indicating the target probability distribution for the message.

Some examples of the method, apparatuses, and non-transitory computer-readable medium described herein may further include operations, features, means, or instructions for communicating the control signaling indicating the message may be generated using a channel coding scheme and the block encoding scheme.

Some examples of the method, apparatuses, and non-transitory computer-readable medium described herein may further include operations, features, means, or instructions for determining that the block encoding scheme may be one of a polar coding scheme, a low-density generator matrix coding scheme, a convolution coding scheme, a turbo coding scheme, a Reed Muller coding scheme, an algebraic coding scheme, or any combination thereof.

In some examples of the method, apparatuses, and non-transitory computer-readable medium described herein, communicating control signaling indicating the block encoding scheme, the determining based on the control signaling.

Some examples of the method, apparatuses, and non-transitory computer-readable medium described herein may further include operations, features, means, or instructions for determining a mapping of the set of multiple information bits to a set of multiple frozen bit locations and the set of multiple shaping bits to a set of multiple information bit locations, where the message may be based on the mapping.

In some examples of the method, apparatuses, and non-transitory computer-readable medium described herein, communicating control signaling indicating the mapping, the determining based on communicating the control signaling.

Some examples of the method, apparatuses, and non-transitory computer-readable medium described herein may further include operations, features, means, or instructions for calculating a set of log likelihood ratio (LLR) values based on the target probability distribution and decoding the set of LLR values according to a decoding operation associated with the block encoding scheme to generate the set of multiple shaping bits.

In some examples of the method, apparatuses, and non-transitory computer-readable medium described herein, a set of multiple information bits may be mapped to a set of multiple frozen bit locations of the block encoding scheme and the set of multiple shaping bits may be based on the set of decoded LLR values.

Some examples of the method, apparatuses, and non-transitory computer-readable medium described herein may further include operations, features, means, or instructions for mapping a second set of multiple information bits and at least one candidate shaped bit to a modulation symbol, determining a conditional distribution based on the target probability distribution, and determining a LLR value for the at least one candidate shaped bit based on the second set of multiple information bits and the conditional distribution associated with the modulation symbol, where calculating the set of LLR values may be based on determining the LLR value for the at least one candidate shaped bit.

In some examples of the method, apparatuses, and non-transitory computer-readable medium described herein, the second set of multiple information bits may be independently distributed from distribution of the set of multiple shaped bits according to the encoding.

Some examples of the method, apparatuses, and non-transitory computer-readable medium described herein may further include operations, features, means, or instructions for shaping the second set of multiple information bits according to the encoding.

Some examples of the method, apparatuses, and non-transitory computer-readable medium described herein may further include operations, features, means, or instructions for shaping the set of multiple shaped bits using a joint decoder for the block encoding scheme and a channel encoding scheme and applying a channel encoding scheme to the set of multiple shaped bits including the set of multiple information bits and the set of multiple shaping bits to generate a set of multiple parity bits using a joint decoder of the block encoding scheme and the channel encoding scheme based on the target probability distribution associated with the block encoding scheme and a second target probability distribution associated with the channel encoding scheme.

Some examples of the method, apparatuses, and non-transitory computer-readable medium described herein may further include operations, features, means, or instructions for calculating a first set of LLR values for the block encoding scheme based on the target probability distribution and calculating a second set of LLR values for the channel encoding scheme for the decoder associated with the channel encoding scheme, the second set of LLR values based on the second target probability distribution corresponding to the set of multiple parity bits, where shaping of the set of multiple shaped bits may be based on the first set of LLR values and the second set of LLR values.

A method for wireless communications is described. The method may include obtaining, from a first device by a second device, a message and decoding the message to generate a set of multiple shaped bits satisfying a target probability distribution associated with a block encoding scheme, the set of multiple shaped bits including a set of multiple information bits and a set of multiple shaping bits.

An apparatus for wireless communications is described. The apparatus may include a processor, memory coupled with the processor, and instructions stored in the memory. The instructions may be executable by the processor to cause the apparatus to obtain, from a first device by a second device, a message and decode the message to generate a set of multiple shaped bits satisfying a target probability distribution associated with a block encoding scheme, the set of multiple shaped bits including a set of multiple information bits and a set of multiple shaping bits.

Another apparatus for wireless communications is described. The apparatus may include means for obtaining, from a first device by a second device, a message and means for decoding the message to generate a set of multiple shaped bits satisfying a target probability distribution associated with a block encoding scheme, the set of multiple shaped bits including a set of multiple information bits and a set of multiple shaping bits.

A non-transitory computer-readable medium storing code for wireless communications is described. The code may include instructions executable by a processor to obtain, from a first device by a second device, a message and decode the message to generate a set of multiple shaped bits satisfying a target probability distribution associated with a block encoding scheme, the set of multiple shaped bits including a set of multiple information bits and a set of multiple shaping bits.

Some examples of the method, apparatuses, and non-transitory computer-readable medium described herein may further include operations, features, means, or instructions for determining the block encoding scheme associated with the target probability distribution for reception of the message.

In some examples of the method, apparatuses, and non-transitory computer-readable medium described herein, communicating, with the first device, control signaling scheduling a transmission of the message and indicating the block encoding scheme, where determining the block encoding scheme may be based on communicating the control signaling.

Some examples of the method, apparatuses, and non-transitory computer-readable medium described herein may further include operations, features, means, or instructions for communicating the control signaling indicating the target probability distribution for the message.

Some examples of the method, apparatuses, and non-transitory computer-readable medium described herein may further include operations, features, means, or instructions for communicating the control signaling indicating the message may be generated using a channel coding scheme and the block encoding scheme.

Some examples of the method, apparatuses, and non-transitory computer-readable medium described herein may further include operations, features, means, or instructions for determining that the block encoding scheme may be one of a polar coding scheme, a low-density generator matrix coding scheme, a convolution coding scheme, a turbo coding scheme, a Reed Muller coding scheme, an algebraic coding scheme, or any combination thereof.

In some examples of the method, apparatuses, and non-transitory computer-readable medium described herein, communicating control signaling indicating the block encoding scheme, the determining based on the control signaling.

Some examples of the method, apparatuses, and non-transitory computer-readable medium described herein may further include operations, features, means, or instructions for determining a mapping of the set of multiple information bits to a set of multiple frozen bit locations and the set of multiple shaping bits to a set of multiple information bits, where decoding the message may be based on the mapping.

In some examples of the method, apparatuses, and non-transitory computer-readable medium described herein, communicating control signaling indicating the block encoding scheme, the determining based on the control signaling.

In some examples of the method, apparatuses, and non-transitory computer-readable medium described herein, a second set of multiple information bits may be independently distributed from a distribution of the set of multiple shaped bits according to the block encoding scheme.

In some examples of the method, apparatuses, and non-transitory computer-readable medium described herein, jointly decoding the set of multiple shaped bits including the set of multiple information bits and the second set of multiple information bits according to a forward error correction decoder associated with a channel encoding scheme and the block encoding scheme, the set of multiple shaped bits including a set of multiple parity bits associated with the channel encoding scheme.

### BRIEF DESCRIPTION OF THE DRAWINGS

FIG. 1 illustrates an example of a wireless communications system that supports probabilistic shaping based on block codes in accordance with one or more aspects of the present disclosure.

FIG. 2 illustrates an example of a wireless communications system that supports probabilistic shaping based on block codes in accordance with one or more aspects of the present disclosure.

FIG. 3 illustrates an example of a signaling diagram that supports probabilistic shaping based on block codes in accordance with one or more aspects of the present disclosure.

FIG. 4 illustrates an example of a signaling diagram that supports probabilistic shaping based on block codes in accordance with one or more aspects of the present disclosure.

FIG. 5 illustrates an example of a shaping scheme that supports probabilistic shaping based on block codes in accordance with one or more aspects of the present disclosure.

FIG. 6 illustrates an example of a bit generation scheme that supports probabilistic shaping based on block codes in accordance with one or more aspects of the present disclosure.

FIG. 7 illustrates an example of a shaping scheme that supports probabilistic shaping based on block codes in accordance with one or more aspects of the present disclosure.

FIG. 8 illustrates an example of an encoding scheme that supports probabilistic shaping based on block codes in accordance with one or more aspects of the present disclosure.

FIGS. 9A and 9B illustrates an examples of shaping schemes that supports probabilistic shaping based on block codes in accordance with one or more aspects of the present disclosure.

FIG. 10 illustrates an example of a process flow that supports probabilistic shaping based on block codes in accordance with one or more aspects of the present disclosure.

FIGS. 11 and 12 illustrate block diagrams of devices that support probabilistic shaping based on block codes in accordance with one or more aspects of the present disclosure.

FIG. 13 illustrates a block diagram of a communications manager that supports probabilistic shaping based on block codes in accordance with one or more aspects of the present disclosure.

FIG. 14 illustrates a diagram of a system including a device that supports probabilistic shaping based on block codes in accordance with one or more aspects of the present disclosure.

FIGS. 15 through 18 illustrate flowcharts showing methods that support probabilistic shaping based on block codes in accordance with one or more aspects of the present disclosure.

FIG. 19 illustrates an example of a network architecture that supports probabilistic shaping based on block codes in accordance with one or more aspects of the present disclosure.

### DETAILED DESCRIPTION

In some wireless communication systems, higher-order modulation, such as quadrature amplitude modulation (QAM) (e.g., 16QAM, 64QAM, 256QAM, etc.) may be used to increase spectral efficiency at improved signal-to-noise ratio (SNR) values. Constellations generated by the modulations may be fixed (e.g., information bit are modulated such that a carrier signal is modulated to a set of desired phase, frequency, and amplitude states, which may be referred to as a constellation), and each constellation point of the constellation may be used with equal probability. In some other examples, non-uniformly distributed coded modulation symbols may be generated by probabilistic shaping. Probabilistic shaping may refer to generating a constellation such that some signal combinations are sent more often, and others less frequently to optimize signal quality at a destination, or to maintain signal quality at varying transmission energies. Probabilistic shaping may transform an information payload (e.g., uniform bits) into non-uniformly distributed bits (e.g., the shaped bits) according to a given target probability distribution. Probabilistic shaping may be based on source code and a source compression algorithm (e.g., arithmetic coding, Huffman code) to shape the information bits to a given probability distribution, followed by the use of a high rate systematic code to encode the shaped information bits. Probabilistic shaping may improve spectral efficiency of coded modulation symbols (e.g., because non-uniformly distributed constellations generated by probabilistic shaping may achieve larger mutual information than uniformly distributed constellations without increasing a signal to noise ratio (SNR).

In some probabilistic shaping schemes, shaping bits may be used to shape information bits by applying a masking, or scrambling to the encoded information bits. The set of shaping bits may be a sequence of bits that may depend on the encoded information bits, such that the combination of the set of shaping bits and the encoded information bits may not be uniformly distributed (e.g., may achieve a target shaped distribution). The transmitting device may perform masking or scrambling of encoded information bits with shaping bits (e.g., via a bit-wise XOR operation), resulting in the non-uniform shaping. In some examples, the transmitting device may transmit the shaping bits (e.g., which are un-shaped but are applied to achieve the overall shaping of the transmission) via the same channel as the shaped information bits (e.g., the data bits). For example, the shaping bits are used to achieve the shaping, but are not shaped themselves, resulting in additional bits to be transmitted along with the shaped information bits. The transmission of both the shaped information bits and the unshaped shaping bits (e.g., the shaping bits applied to the information bits to generate the shaped non-uniform distribution) may result in increased signaling overhead, increased system latency, as well as increased delay on the decoding side.

Techniques described herein support using block encoding schemes (e.g., polar coding) and a probabilistic shaping framework to generate shaped bits that include both information bits (e.g., data) and shaping bits (e.g., a set of bits to be scrambled with or masking the information bits), without the need to convey extra information (e.g., in addition to the shaped bits) to the receiving device. The transmitter may use a decoder such as a polar decoder (e.g., a modem configured for both coding and decoding) to determine a set of shaping bits based on the information bits. Both the shaping bits and information bits are shaped, removing the need to convey extra information about the shaping bits to the receiver. The techniques may also include mapping information bits to the frozen bit locations of the polar code (e.g., locations in the polar code associated with all zero bits), and the shaping bits to the information bit locations of the polar code (e.g., locations in the polar code associated with information bits), such that the encoded (e.g., shaped) bits from the polar encoder satisfy a target probability distribution. In some examples, the transmitting device may use the block encoding scheme (e.g., a polar code) and a channel encoding scheme (e.g., using a forward error correction scheme) to generate a set of parity bits such that the transmitting device transmits a complete set of shaped bits including information bits, shaping bits, and parity bits.

A set of log likelihood ratio (LLR) values (e.g., a set of values indicating how well a model fits a data set, where a higher LLR value indicates a better fit of a model to the data set than a lower value) may be calculated based on the target distribution of the probabilistic shaping framework and other non-information bits (e.g., to be mapped to a same modulation symbol). The polar decoder may decode the LLR values, where frozen bits are filled with information bits. The decoder determines the set of shaping bits from the LLR values, where the shaping bits correspond to the information bits associated with the decoder. The transmitting device may map candidate shaped bits (e.g., a particular bit of a set of bits mapped to a same modulation symbol) to a modulation symbol. In some examples, shaped bits may be based on the target probability distribution, and may all be mapped to a same bit-location of a modulation symbol. The transmitting device may map multiple bits according to an independent distribution, which may be referred to as an unconditional shaping (e.g., the LLR of each bit v is determined independently from the other data bits being mapped to the same modulation symbol), or according to a conditional distribution (e.g., the LLR of each bit v is determined from the other data bits being mapped to the same modulation symbol). Shaping techniques based on block encoding schemes may result in increased throughput, decreased system latency, improved reliability of wireless signaling, decreased signaling overhead, because the described shaping techniques allow for the improved power efficiency and signaling reliability of non-uniform distributions and probabilistic shaping, without the extra signaling overhead of transmitting unshaped shaping bits along with shaped information bits (e.g., as performed by other probabilistic shaping techniques). Thus, the techniques described herein result in improved throughput (e.g., because additional unshaped bits are not transmitted along with shaped information bits), with reduced power expenditures, resulting in improved system efficiency, decreased system latency, and improved user experience.

Aspects of the disclosure are initially described in the context of wireless communications systems. Aspects of the disclosure are further illustrated by and described with reference to wireless communications systems, signaling diagrams, shaping schemes, bit generation schemes, encoding schemes, and process flows. Aspects of the disclosure are further illustrated by and described with reference to apparatus diagrams, system diagrams, and flowcharts that relate to probabilistic shaping based on block codes.

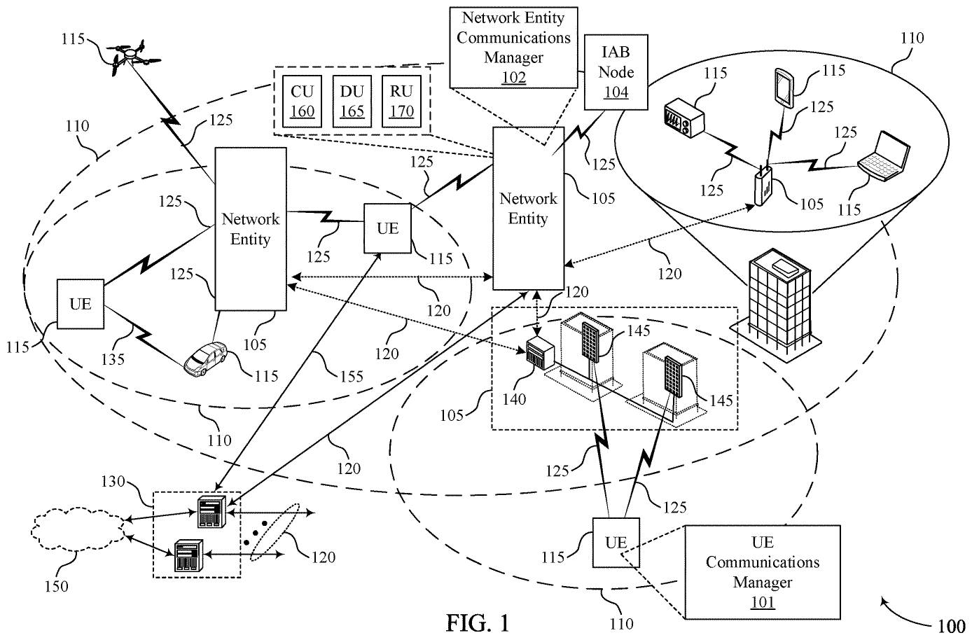

FIG. 1 illustrates an example of a wireless communications system 100 that supports probabilistic shaping based on block codes in accordance with one or more aspects of the present disclosure. The wireless communications system 100 may include one or more network entities 105, one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via one or more communication links 125 (e.g., a radio frequency (RF) access link). For example, a network entity 105 may support a coverage area 110 (e.g., a geographic coverage area) over which the UEs 115 and the network entity 105 may establish one or more communication links 125. The coverage area 110 may be an example of a geographic area over which a network entity 105 and a user equipment (UE) 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with the core network 130, or with one another, or both. For example, network entities 105 may communicate with the core network 130 via one or more backhaul communication links 120 (e.g., in accordance with an S1, N2, N3, or other interface protocol). In some examples, network entities 105 may communicate with one another via a backhaul communication link 120 (e.g., in accordance with an X2, Xn, or other interface protocol) either directly (e.g., directly between network entities 105) or indirectly (e.g., via a core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication links 120, midhaul communication links 162, or fronthaul communication links 168 may be or include one or more wired links (e.g., an electrical link, an optical fiber link), one or more wireless links (e.g., a radio link, a wireless optical link), among other examples or various combinations thereof. A UE 115 may communicate with the core network 130 via a communication link 155.

One or more of the network entities 105 described herein may include or may be referred to as a base station 140 (e.g., a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within a single network entity 105 (e.g., a single RAN node, such as a base station 140). In some examples, one or more network entities 105 may communicate with other wireless device via one or more repeaters 145 (e.g., such as intelligent reflective surfaces, IAB notes, among other examples).

In the wireless communications system 100 a UE 115 and a network entity 105 (e.g., an eNodeB (eNB), a next-generation NodeB or a giga-NodeB, either of which may be referred to as a gNB, or some other base station), may support wireless communications over one or multiple radio access technologies. Examples of radio access technologies include 4G systems, such as LTE systems, and 5G systems, which may be referred to as NR systems. The wireless communications system 100 may be configured to support techniques for probabilistic shaping based on block codes as described herein. For example, one or more devices may include a UE communications manager 101, a network entity communications manager 102, or any combination thereof, which may be examples of communications managers as described herein. The UE 115 and the network entity 105 may perform, via the communications managers, bit shaping and encoding, or deshaping and decoding procedures. For example, a transmitting device may transmit (e.g., the UE 115 may transmit, via the communications manager 101, or the network entity 105 may transmit, via the communications manager 102) a message shaped using a block encoding scheme such that shaped bits of the message include shaping bits and information bits. The communications managers may further be operable to perform the techniques described herein.

In some examples, a network entity 105 may be implemented in a disaggregated architecture (e.g., a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU) 160, a distributed unit (DU) 165, a radio unit (RU) 170, a RAN Intelligent Controller (RIC) 175 (e.g., a Near-Real Time RIC (Near-RT RIC), a Non-Real Time RIC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or more RUs 170). In some cases, a functional split between a CU 160 and a DU 165, or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (e.g., F1, F1-c, F1-u), and a DU 165 may be connected to one or more RUs 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities 105 that are in communication via such communication links.

Techniques described herein, in addition to or as an alternative to be carried out between UEs 115 and network entities 105, may be implemented via additional or alternative wireless devices, including IAB nodes 104, distributed units (DUs) 165, centralized units (CUs) 160, radio units (RUs) 170, and the like. For example, in some implementations, aspects described herein may be implemented in the context of a disaggregated radio access network (RAN) architecture (e.g., open RAN architecture). In a disaggregated architecture, the RAN may be split into three areas of functionality corresponding to the CU 160, the DU 165, and the RU 170. The split of functionality between the CU 160, DU 165, and RU 175 is flexible and as such gives rise to numerous permutations of different functionalities depending upon which functions (e.g., MAC functions, baseband functions, radio frequency functions, and any combinations thereof) are performed at the CU 160, DU 165, and RU 175. For example, a functional split of the protocol stack may be employed between a DU 165 and an RU 170 such that the DU 165 may support one or more layers of the protocol stack and the RU 170 may support one or more different layers of the protocol stack.

Some wireless communications systems (e.g., wireless communications system 100), infrastructure and spectral resources for NR access may additionally support wireless backhaul link capabilities in supplement to wireline backhaul connections, providing an IAB network architecture. One or more network entities 105 may include CUs 160, DUs 165, and RUs 170 and may be referred to as donor network entities 105 or IAB donors. One or more DUs 165 (e.g., and/or RUs 170) associated with a donor network entity 105 may be partially controlled by CUs 160 associated with the donor network entity 105. The one or more donor network entities 105 (e.g., IAB donors) may be in communication with one or more additional network entities 105 (e.g., IAB nodes 104) via supported access and backhaul links. IAB nodes 104 may support mobile terminal (MT) functionality controlled and/or scheduled by DUs 165 of a coupled IAB donor. In addition, the IAB nodes 104 may include DUs 165 that support communication links with additional entities (e.g., IAB nodes 104, UEs 115, etc.) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

In some examples, the wireless communications system 100 may include a core network 130 (e.g., a next generation core network (NGC)), one or more IAB donors, IAB nodes 104, and UEs 115, where IAB nodes 104 may be partially controlled by each other and/or the IAB donor. The IAB donor and IAB nodes 104 may be examples of aspects of network entities 105. IAB donor and one or more IAB nodes 104 may be configured as (e.g., or in communication according to) some relay chain.

For instance, an access network (AN) or RAN may refer to communications between access nodes (e.g., IAB donor), IAB nodes 104, and one or more UEs 115. The IAB donor may facilitate connection between the core network 130 and the AN (e.g., via a wireline or wireless connection to the core network 130). That is, an IAB donor may refer to a RAN node with a wireline or wireless connection to core network 130. The IAB donor may include a CU 160 and at least one DU 165 (e.g., and RU 170), where the CU 160 may communicate with the core network 130 over an NG interface (e.g., some backhaul link). The CU 160 may host layer 3 (L3) (e.g., RRC, service data adaption protocol (SDAP), PDCP, etc.) functionality and signaling. The at least one DU 165 and/or RU 170 may host lower layer, such as layer 1 (L1) and layer 2 (L2) (e.g., RLC, MAC, physical (PHY), etc.) functionality and signaling, and may each be at least partially controlled by the CU 160. The DU 165 may support one or multiple different cells. IAB donor and IAB nodes 104 may communicate over an F1 interface according to some protocol that defines signaling messages (e.g., F1 AP protocol). Additionally, CU 160 may communicate with the core network over an NG interface (which may be an example of a portion of backhaul link), and may communicate with other CUs 160 (e.g., a CU 160 associated with an alternative IAB donor) over an Xn-C interface (which may be an example of a portion of a backhaul link).

IAB nodes 104 may refer to a RAN node that provides IAB functionality (e.g., access for UEs 115, wireless self-backhauling capabilities, etc.). IAB nodes 104 may include a DU 165 and an MT. A DU 165 may act as a distributed scheduling node towards child nodes associated with the IAB node 104, and the MT may act as a scheduled node towards parent nodes associated with the IAB node 104. That is, an IAB donor may be referred to as a parent node in communication with one or more child nodes (e.g., an IAB donor may relay transmissions for UEs through one or more other IAB nodes 104). Additionally, an IAB node 104 may also be referred to as a parent node or a child node to other IAB nodes 104, depending on the relay chain or configuration of the AN. Therefore, the MT entity of IAB nodes 104 (e.g., MTs) may provide a Uu interface for a child node to receive signaling from a parent IAB node 104, and the DU interface (e.g., DUs 165) may provide a Uu interface for a parent node to signal to a child IAB node 104 or UE 115.

For example, IAB node 104 may be referred to a parent node associated with IAB node, and a child node associated with IAB donor. The IAB donor may include a CU 160 with a wireline (e.g., optical fiber) or wireless connection to the core network and may act as parent node to IAB nodes 104. For example, the DU 165 of IAB donor may relay transmissions to UEs 115 through IAB nodes 104, and may directly signal transmissions to a UE 115. The CU 160 of IAB donor may signal communication link establishment via an F1 interface to IAB nodes 104, and the IAB nodes 104 may schedule transmissions (e.g., transmissions to the UEs 115 relayed from the IAB donor) through the DUs 165. That is, data may be relayed to and from IAB nodes 104 via signaling over an NR Uu interface to MT of the IAB node 104. Communications with IAB node 104 may be scheduled by DU 165 of IAB donor and communications with IAB node 104 may be scheduled by DU 165 of IAB node 104.

In the case of the techniques described herein applied in the context of a disaggregated RAN architecture, one or more components of the disaggregated RAN architecture (e.g., one or more IAB nodes 104 or components of IAB nodes 104) may be configured to support techniques for large round trip times in random access channel procedures as described herein. For example, some operations described as being performed by a UE 115 or a network entity 105 may additionally or alternatively be performed by components of the disaggregated RAN architecture (e.g., IAB nodes, DUs, CUs, etc.).

As described herein, a node, which may be referred to as a node, a network node, a network entity 105, or a wireless node, may be a base station (e.g., any base station described herein), a UE 115 (e.g., any UE described herein), a network controller, an apparatus, a device, a computing system, one or more components, and/or another suitable processing entity configured to perform any of the techniques described herein. For example, a network node may be a UE 115. As another example, a network node may be a base station. As another example, a first network node may be configured to communicate with a second network node or a third network node. In one aspect of this example, the first network node may be a UE 115, the second network node may be a base station, and the third network node may be a UE 115. In another aspect of this example, the first network node may be a UE 115, the second network node may be a base station, and the third network node may be a base station. In yet other aspects of this example, the first, second, and third network nodes may be different relative to these examples. Similarly, reference to a UE 115, base station, apparatus, device, computing system, or the like may include disclosure of the UE 115, base station, apparatus, device, computing system, or the like being a network node. For example, disclosure that a UE 115 is configured to receive information from a base station also discloses that a first network node is configured to receive information from a second network node. Consistent with this disclosure, once a specific example is broadened in accordance with this disclosure (e.g., a UE 115 is configured to receive information from a base station also discloses that a first network node is configured to receive information from a second network node), the broader example of the narrower example may be interpreted in the reverse, but in a broad open-ended way. In the example above where a UE 115 being configured to receive information from a base station also discloses that a first network node being configured to receive information from a second network node, the first network node may refer to a first UE 115, a first base station, a first apparatus, a first device, a first computing system, a first one or more components, a first processing entity, or the like configured to receive the information; and the second network node may refer to a second UE 115, a second base station, a second apparatus, a second device, a second computing system, a second one or more components, a second processing entity, or the like.

As described herein, communication of information (e.g., any information, signal, or the like) may be described in various aspects using different terminology. Disclosure of one communication term includes disclosure of other communication terms. For example, a first network node may be described as being configured to transmit information to a second network node. In this example and consistent with this disclosure, disclosure that the first network node is configured to transmit information to the second network node includes disclosure that the first network node is configured to provide, send, output, communicate, or transmit information to the second network node. Similarly, in this example and consistent with this disclosure, disclosure that the first network node is configured to transmit information to the second network node includes disclosure that the second network node is configured to receive, obtain, or decode the information that is provided, sent, output, communicated, or transmitted by the first network node.

In wireless communications systems (e.g., wireless communications system 100), infrastructure and spectral resources for radio access may support wireless backhaul link capabilities to supplement wired backhaul connections, providing an IAB network architecture (e.g., to a core network 130). In some cases, in an IAB network, one or more network entities 105 (e.g., IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (e.g., a donor base station 140). The one or more donor network entities 105 (e.g., IAB donors) may be in communication with one or more additional network entities 105 (e.g., IAB nodes 104) via supported access and backhaul links (e.g., backhaul communication links 120). IAB nodes 104 may include an IAB mobile termination (IAB-MT) controlled (e.g., scheduled) by DUs 165 of a coupled IAB donor. An IAB-MT may include an independent set of antennas for relay of communications with UEs 115, or may share the same antennas (e.g., of an RU 170) of an IAB node 104 used for access via the DU 165 of the IAB node 104 (e.g., referred to as virtual IAB-MT (vIAB-MT)). In some examples, the IAB nodes 104 may include DUs 165 that support communication links with additional entities (e.g., IAB nodes 104, UEs 115) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

For instance, an access network (AN) or RAN may include communications between access nodes (e.g., an IAB donor), IAB nodes 104, and one or more UEs 115. The IAB donor may facilitate connection between the core network 130 and the AN (e.g., via a wired or wireless connection to the core network 130). That is, an IAB donor may refer to a RAN node with a wired or wireless connection to core network 130. The IAB donor may include a CU 160 and at least one DU 165 (e.g., and RU 170), in which case the CU 160 may communicate with the core network 130 via an interface (e.g., a backhaul link). IAB donor and IAB nodes 104 may communicate via an F1 interface according to a protocol that defines signaling messages (e.g., an F1 AP protocol). Additionally, or alternatively, the CU 160 may communicate with the core network via an interface, which may be an example of a portion of backhaul link, and may communicate with other CUs 160 (e.g., a CU 160 associated with an alternative IAB donor) via an Xn-C interface, which may be an example of a portion of a backhaul link.

An IAB node 104 may refer to a RAN node that provides IAB functionality (e.g., access for UEs 115, wireless self-backhauling capabilities). A DU 165 may act as a distributed scheduling node towards child nodes associated with the IAB node 104, and the IAB-MT may act as a scheduled node towards parent nodes associated with the IAB node 104. That is, an IAB donor may be referred to as a parent node in communication with one or more child nodes (e.g., an IAB donor may relay transmissions for UEs through one or more other IAB nodes 104). Additionally, or alternatively, an IAB node 104 may also be referred to as a parent node or a child node to other IAB nodes 104, depending on the relay chain or configuration of the AN. Therefore, the IAB-MT entity of IAB nodes 104 may provide a Uu interface for a child IAB node 104 to receive signaling from a parent IAB node 104, and the DU interface (e.g., DUs 165) may provide a Uu interface for a parent IAB node 104 to signal to a child IAB node 104 or UE 115.

For example, IAB node 104 may be referred to as a parent node that supports communications for a child IAB node, or referred to as a child IAB node associated with an IAB donor, or both. The IAB donor may include a CU 160 with a wired or wireless connection (e.g., a backhaul communication link 120) to the core network 130 and may act as parent node to IAB nodes 104. For example, the DU 165 of IAB donor may relay transmissions to UEs 115 through IAB nodes 104, or may directly signal transmissions to a UE 115, or both. The CU 160 of IAB donor may signal communication link establishment via an F1 interface to IAB nodes 104, and the IAB nodes 104 may schedule transmissions (e.g., transmissions to the UEs 115 relayed from the IAB donor) through the DUs 165. That is, data may be relayed to and from IAB nodes 104 via signaling via an NR Uu interface to MT of the IAB node 104. Communications with IAB node 104 may be scheduled by a DU 165 of IAB donor and communications with IAB node 104 may be scheduled by DU 165 of IAB node 104.

In the case of the techniques described herein applied in the context of a disaggregated RAN architecture, one or more components of the disaggregated RAN architecture may be configured to support probabilistic shaping based on block codes as described herein. For example, some operations described as being performed by a UE 115 or a network entity 105 (e.g., a base station 140) may additionally, or alternatively, be performed by one or more components of the disaggregated RAN architecture (e.g., IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (e.g., an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities 105).

In some examples, such as in a carrier aggregation configuration, a carrier may also have acquisition signaling or control signaling that coordinates operations for other carriers. A carrier may be associated with a frequency channel (e.g., an evolved universal mobile telecommunication system terrestrial radio access (E-UTRA) absolute RF channel number (EARFCN)) and may be identified according to a channel raster for discovery by the UEs 115. A carrier may be operated in a standalone mode, in which case initial acquisition and connection may be conducted by the UEs 115 via the carrier, or the carrier may be operated in a non-standalone mode, in which case a connection is anchored using a different carrier (e.g., of the same or a different radio access technology).

The communication links 125 shown in the wireless communications system 100 may include downlink transmissions (e.g., forward link transmissions) from a network entity 105 to a UE 115, uplink transmissions (e.g., return link transmissions) from a UE 115 to a network entity 105, or both, among other configurations of transmissions. Carriers may carry downlink or uplink communications (e.g., in an FDD mode) or may be configured to carry downlink and uplink communications (e.g., in a TDD mode).

A carrier may be associated with a particular bandwidth of the RF spectrum and, in some examples, the carrier bandwidth may be referred to as a “system bandwidth” of the carrier or the wireless communications system 100. For example, the carrier bandwidth may be one of a set of bandwidths for carriers of a particular radio access technology (e.g., 1.4, 3, 5, 10, 15, 20, 40, or 80 megahertz (MHz)). Devices of the wireless communications system 100 (e.g., the network entities 105, the UEs 115, or both) may have hardware configurations that support communications using a particular carrier bandwidth or may be configurable to support communications using one of a set of carrier bandwidths. In some examples, the wireless communications system 100 may include network entities 105 or UEs 115 that support concurrent communications using carriers associated with multiple carrier bandwidths. In some examples, each served UE 115 may be configured for operating using portions (e.g., a sub-band, a BWP) or all of a carrier bandwidth.

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

One or more numerologies for a carrier may be supported, and a numerology may include a subcarrier spacing (Δf) and a cyclic prefix. A carrier may be divided into one or more BWPs having the same or different numerologies. In some examples, a UE 115 may be configured with multiple BWPs. In some examples, a single BWP for a carrier may be active at a given time and communications for the UE 115 may be restricted to one or more active BWPs.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

A network entity 105 may provide communication coverage via one or more cells, for example a macro cell, a small cell, a hot spot, or other types of cells, or any combination thereof. The term “cell” may refer to a logical communication entity used for communication with a network entity 105 (e.g., using a carrier) and may be associated with an identifier for distinguishing neighboring cells (e.g., a physical cell identifier (PCID), a virtual cell identifier (VCID), or others). In some examples, a cell also may refer to a coverage area 110 or a portion of a coverage area 110 (e.g., a sector) over which the logical communication entity operates. Such cells may range from smaller areas (e.g., a structure, a subset of structure) to larger areas depending on various factors such as the capabilities of the network entity 105. For example, a cell may be or include a building, a subset of a building, or exterior spaces between or overlapping with coverage areas 110, among other examples.

A macro cell generally covers a relatively large geographic area (e.g., several kilometers in radius) and may allow unrestricted access by the UEs 115 with service subscriptions with the network provider supporting the macro cell. A small cell may be associated with a lower-powered network entity 105 (e.g., a lower-powered base station 140), as compared with a macro cell, and a small cell may operate using the same or different (e.g., licensed, unlicensed) frequency bands as macro cells. Small cells may provide unrestricted access to the UEs 115 with service subscriptions with the network provider or may provide restricted access to the UEs 115 having an association with the small cell (e.g., the UEs 115 in a closed subscriber group (CSG), the UEs 115 associated with users in a home or office). A network entity 105 may support one or multiple cells and may also support communications via the one or more cells using one or multiple component carriers.

In some examples, a carrier may support multiple cells, and different cells may be configured according to different protocol types (e.g., MTC, narrowband IoT (NB-IoT), enhanced mobile broadband (eMBB)) that may provide access for different types of devices.

In some examples, a network entity 105 (e.g., a base station 140, an RU 170) may be movable and therefore provide communication coverage for a moving coverage area 110. In some examples, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may support synchronous or asynchronous operation. For synchronous operation, network entities 105 (e.g., base stations 140) may have similar frame timings, and transmissions from different network entities 105 may be approximately aligned in time. For asynchronous operation, network entities 105 may have different frame timings, and transmissions from different network entities 105 may, in some examples, not be aligned in time. The techniques described herein may be used for either synchronous or asynchronous operations.

Some UEs 115, such as MTC or IoT devices, may be low cost or low complexity devices and may provide for automated communication between machines (e.g., via Machine-to-Machine (M2M) communication). M2M communication or MTC may refer to data communication technologies that allow devices to communicate with one another or a network entity 105 (e.g., a base station 140) without human intervention. In some examples, M2M communication or MTC may include communications from devices that integrate sensors or meters to measure or capture information and relay such information to a central server or application program that uses the information or presents the information to humans interacting with the application program. Some UEs 115 may be designed to collect information or enable automated behavior of machines or other devices. Examples of applications for MTC devices include smart metering, inventory monitoring, water level monitoring, equipment monitoring, healthcare monitoring, wildlife monitoring, weather and geological event monitoring, fleet management and tracking, remote security sensing, physical access control, and transaction-based business charging.

Some UEs 115 may be configured to employ operating modes that reduce power consumption, such as half-duplex communications (e.g., a mode that supports one-way communication via transmission or reception, but not transmission and reception concurrently). In some examples, half-duplex communications may be performed at a reduced peak rate. Other power conservation techniques for the UEs 115 include entering a power saving deep sleep mode when not engaging in active communications, operating using a limited bandwidth (e.g., according to narrowband communications), or a combination of these techniques. For example, some UEs 115 may be configured for operation using a narrowband protocol type that is associated with a defined portion or range (e.g., set of subcarriers or resource blocks (RBs)) within a carrier, within a guard-band of a carrier, or outside of a carrier.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs 115 via a device-to-device (D2D) communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to each of the other UEs 115 in the group. In some examples, a network entity 105 may facilitate the scheduling of resources for D2D communications. In some other examples, D2D communications may be carried out between the UEs 115 without an involvement of a network entity 105.

In some systems, a D2D communication link 135 may be an example of a communication channel, such as a sidelink communication channel, between vehicles (e.g., UEs 115). In some examples, vehicles may communicate using vehicle-to-everything (V2X) communications, vehicle-to-vehicle (V2V) communications, or some combination of these. A vehicle may signal information related to traffic conditions, signal scheduling, weather, safety, emergencies, or any other information relevant to a V2X system. In some examples, vehicles in a V2X system may communicate with roadside infrastructure, such as roadside units, or with the network via one or more network nodes (e.g., network entities 105, base stations 140, RUs 170) using vehicle-to-network (V2N) communications, or with both.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than 100 kilometers) compared to communications using the smaller frequencies and longer waves of the high frequency (HF) or very high frequency (VHF) portion of the spectrum below 300 MHz.

The wireless communications system 100 may also operate using a super high frequency (SHF) region, which may be in the range of 3 GHz to 30 GHz, also known as the centimeter band, or using an extremely high frequency (EHF) region of the spectrum (e.g., from 30 GHz to 300 GHz), also known as the millimeter band. In some examples, the wireless communications system 100 may support millimeter wave (mmW) communications between the UEs 115 and the network entities 105 (e.g., base stations 140, RUs 170), and EHF antennas of the respective devices may be smaller and more closely spaced than UHF antennas. In some examples, such techniques may facilitate using antenna arrays within a device. The propagation of EHF transmissions, however, may be subject to even greater attenuation and shorter range than SHF or UHF transmissions. The techniques disclosed herein may be employed across transmissions that use one or more different frequency regions, and designated use of bands across these frequency regions may differ by country or regulating body.

The electromagnetic spectrum is often subdivided, based on frequency/wavelength, into various classes, bands, channels, etc. In 5G NR two initial operating bands have been identified as frequency range designations FR1 (410 MHz-7.125 GHz) and FR2 (24.25 GHz-52.6 GHz). It should be understood that although a portion of FR1 is greater than 6 GHz, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHz-24.25 GHz). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHz), and FR5 (114.25 GHz-300 GHz). Each of these higher frequency bands falls within the EHF band.

With the above aspects in mind, unless specifically stated otherwise, it should be understood that the term “sub-6 GHz” or the like if used herein may broadly represent frequencies that may be less than 6 GHz, may be within FR1, or may include mid-band frequencies. Further, unless specifically stated otherwise, it should be understood that the term “millimeter wave” or the like if used herein may broadly represent frequencies that may include mid-band frequencies, may be within FR2, FR4, FR4-a or FR4-1, and/or FR5, or may be within the EHF band.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

The network entities 105 or the UEs 115 may use MIMO communications to exploit multipath signal propagation and increase spectral efficiency by transmitting or receiving multiple signals via different spatial layers. Such techniques may be referred to as spatial multiplexing. The multiple signals may, for example, be transmitted by the transmitting device via different antennas or different combinations of antennas. Likewise, the multiple signals may be received by the receiving device via different antennas or different combinations of antennas. Each of the multiple signals may be referred to as a separate spatial stream and may carry information associated with the same data stream (e.g., the same codeword) or different data streams (e.g., different codewords). Different spatial layers may be associated with different antenna ports used for channel measurement and reporting. MIMO techniques include single-user MIMO (SU-MIMO), for which multiple spatial layers are transmitted to the same receiving device, and multiple-user MIMO (MU-MIMO), for which multiple spatial layers are transmitted to multiple devices.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

A network entity 105 or a UE 115 may use beam sweeping techniques as part of beamforming operations. For example, a network entity 105 (e.g., a base station 140, an RU 170) may use multiple antennas or antenna arrays (e.g., antenna panels) to conduct beamforming operations for directional communications with a UE 115. Some signals (e.g., synchronization signals, reference signals, beam selection signals, or other control signals) may be transmitted by a network entity 105 multiple times along different directions. For example, the network entity 105 may transmit a signal according to different beamforming weight sets associated with different directions of transmission. Transmissions along different beam directions may be used to identify (e.g., by a transmitting device, such as a network entity 105, or by a receiving device, such as a UE 115) a beam direction for later transmission or reception by the network entity 105.

Some signals, such as data signals associated with a particular receiving device, may be transmitted by transmitting device (e.g., a transmitting network entity 105, a transmitting UE 115) along a single beam direction (e.g., a direction associated with the receiving device, such as a receiving network entity 105 or a receiving UE 115). In some examples, the beam direction associated with transmissions along a single beam direction may be determined based on a signal that was transmitted along one or more beam directions. For example, a UE 115 may receive one or more of the signals transmitted by the network entity 105 along different directions and may report to the network entity 105 an indication of the signal that the UE 115 received with a highest signal quality or an otherwise acceptable signal quality.

In some examples, transmissions by a device (e.g., by a network entity 105 or a UE 115) may be performed using multiple beam directions, and the device may use a combination of digital precoding or beamforming to generate a combined beam for transmission (e.g., from a network entity 105 to a UE 115). The UE 115 may report feedback that indicates precoding weights for one or more beam directions, and the feedback may correspond to a configured set of beams across a system bandwidth or one or more sub-bands. The network entity 105 may transmit a reference signal (e.g., a cell-specific reference signal (CRS), a channel state information reference signal (CSI-RS)), which may be precoded or unprecoded. The UE 115 may provide feedback for beam selection, which may be a precoding matrix indicator (PMI) or codebook-based feedback (e.g., a multi-panel type codebook, a linear combination type codebook, a port selection type codebook). Although these techniques are described with reference to signals transmitted along one or more directions by a network entity 105 (e.g., a base station 140, an RU 170), a UE 115 may employ similar techniques for transmitting signals multiple times along different directions (e.g., for identifying a beam direction for subsequent transmission or reception by the UE 115) or for transmitting a signal along a single direction (e.g., for transmitting data to a receiving device).

A receiving device (e.g., a UE 115) may perform reception operations in accordance with multiple receive configurations (e.g., directional listening) when receiving various signals from a receiving device (e.g., a network entity 105), such as synchronization signals, reference signals, beam selection signals, or other control signals. For example, a receiving device may perform reception in accordance with multiple receive directions by receiving via different antenna subarrays, by processing received signals according to different antenna subarrays, by receiving according to different receive beamforming weight sets (e.g., different directional listening weight sets) applied to signals received at multiple antenna elements of an antenna array, or by processing received signals according to different receive beamforming weight sets applied to signals received at multiple antenna elements of an antenna array, any of which may be referred to as “listening” according to different receive configurations or receive directions. In some examples, a receiving device may use a single receive configuration to receive along a single beam direction (e.g., when receiving a data signal). The single receive configuration may be aligned along a beam direction determined based on listening according to different receive configuration directions (e.g., a beam direction determined to have a highest signal strength, highest signal-to-noise ratio (SNR), or otherwise acceptable signal quality based on listening according to multiple beam directions).

The wireless communications system 100 may be a packet-based network that operates according to a layered protocol stack. In the user plane, communications at the bearer or PDCP layer may be IP-based. An RLC layer may perform packet segmentation and reassembly to communicate via logical channels. A MAC layer may perform priority handling and multiplexing of logical channels into transport channels. The MAC layer also may implement error detection techniques, error correction techniques, or both to support retransmissions to improve link efficiency. In the control plane, an RRC layer may provide establishment, configuration, and maintenance of an RRC connection between a UE 115 and a network entity 105 or a core network 130 supporting radio bearers for user plane data. A PHY layer may map transport channels to physical channels.

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., a communication link 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in poor radio conditions (e.g., low signal-to-noise conditions). In some examples, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

In some examples a transmitting device (e.g., a UE 115 or a network entity 105) may support shaping of bits in block encoding schemes (e.g., polar coding) and a probabilistic shaping framework to generate shaped bits that include both information bits (e.g., data) and shaping bits, without the need to convey extra information (e.g., in addition to the shaped bits) to the receiving device. The transmitter may use a decoder such as a polar decoder (e.g., a modem configured for both coding and decoding) to determine a set of shaping bits based on the information bits. Both the shaping bits and information bits are shaped, removing the need to convey extra information about the shaping bits to the receiver. The techniques may also include mapping information bits to the frozen bit locations of the polar code (e.g., locations in the polar code associated with all zero bits), and the shaping bits to the information bit locations of the polar code (e.g., locations in the polar code associated with information bits), such that the encoded (e.g., shaped) bits from the polar encoder satisfy a target probability distribution. In some examples, the transmitting device may use the block encoding scheme (e.g., a polar code) and a channel encoding scheme (e.g., using a forward error correction scheme) to generate a set of parity bits such that the transmitting device transmits a complete set of shaped bits including information bits, shaping bits, and parity bits.

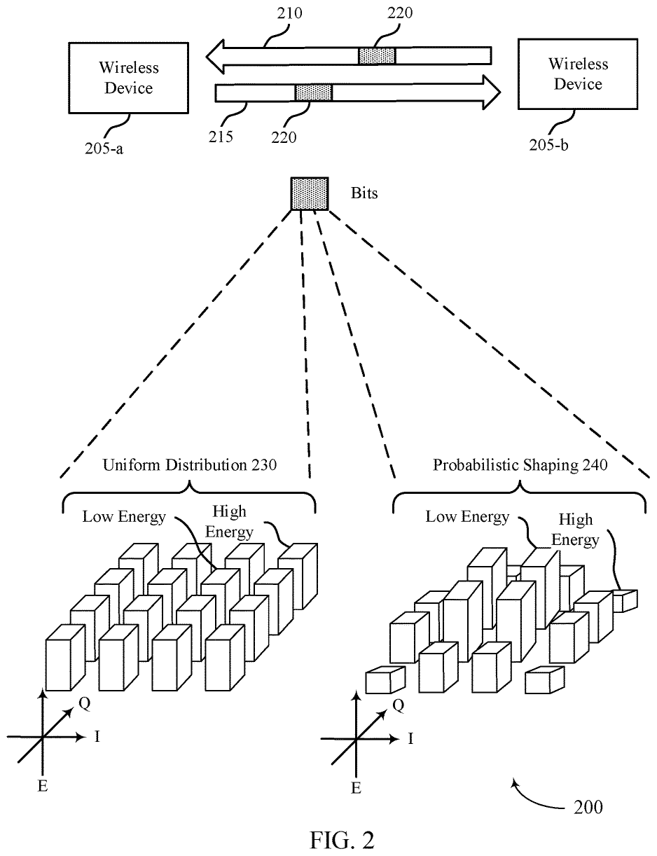

FIG. 2 illustrates an example of a wireless communications system 200 that supports probabilistic shaping based on block codes in accordance with one or more aspects of the present disclosure. The wireless communications system 200 may implement aspects of the wireless communications system 100 or may be implemented by aspects of the wireless communications system 100. For example, the wireless communications system 200 may include a wireless device 205-a and a wireless device 205-b, which may be examples of corresponding devices described herein (e.g., a network entity 105, a UE 115). The wireless device 205-a may communicate with the wireless device 205-b via the communication link 210 and the communication link 215. The wireless devices 205 may communicate one or more bits 220. The communication link 210 and the communication link 215 may be either the uplink or the downlink, and in some cases may be a sidelink connection. A device transmitting a signal, or a message, (e.g., in the uplink, downlink, or sidelink) may be referred to as a transmitting device, and a device receiving the transmitted signal (e.g., in the uplink, downlink, or sidelink) may be referred to as a receiving device.

Generally, the wireless communications system 200 illustrates an example of the wireless device 205-a and the wireless device 205-b communicating via the communication link 210 and the communication link 215. For example, the wireless device 205-a, the wireless device 205-b, or both, may transmit a signal modulated to represent a set of bits 220. For example, the bits 220 may be transmitted via a message including a distribution of modulated symbols, where each symbol in the distribution may represent one or more bits.

Some wireless communications systems (e.g., cellular, Wi-Fi) may utilize higher order modulation (e.g., 16 quadrature amplitude modulation (QAM), 64 QAM, 256 QAM, 1024QAM, 4096QAM) to increase spectral efficiency for wireless transmissions at higher signal-to-noise-ratio (SNR) values. In such systems, constellations of modulated symbols may be fixed (e.g., may be square constellations), where each constellation point (e.g., value, symbol) may have a same probability of being used as another constellation point (e.g., each constellation point may be used with equal probability). In some examples, as information rate increases, the SNR of uniform modulation (e.g., 16 QAM, 64 QAM, 256 QAM, quadrature phase shift keying (QPSK)) as well as probabilistic shaping (e.g., a uniform distribution 230 with a same energy (E) for each constellation point defined by I (in-phase carrier) on the X axis and Q (quadrature carrier) on the Y axis). Optimized constellation distribution may plateau (e.g., initially, for a given modulation scheme or shaping scheme, an increase in SNR may result in an increase in information rate, however at some point, SNR may continue to increase while information rate remains the same). Probabilistic shaping may plateau at the same information rate as the 256 QAM, and plateau at higher information rates than other uniform QAM.

In some cases, the distribution of symbols may be shaped such that different symbols may have different probabilities of usage, where such a distribution may be referred to as a non-uniform distribution of symbols. For example, a non-uniform distribution of symbols may include a first set of symbols with respective probabilities of usage below a first probability level and a second set of symbols with respective probabilities of usage above or equal to the first probability level. In such cases, the first set of symbols may include one or more probabilities below the first probability level (e.g., different probabilities below the first probability level) and the second set of symbols may include one or more probabilities above or equal to the first probability level (e.g., different probabilities above or equal to the first probability level).

A non-uniform distribution of symbols may be shaped using one or more probabilistic shaping techniques (e.g., according to probabilistic shaping 240). Probabilistic shaping may be a technique used to increase spectral efficiency of the coded modulation, and may generate non-uniformly distributed coded modulation symbols, or non-uniformly distributed constellations. In some examples, non-uniformly distributed QAM may have a higher capacity than a uniformly distributed QAM. Such non-uniform distributions may result in higher transmission capacities, higher spectral efficiencies, or generally higher communication quality than uniform symbol distributions. For example, non-uniformly distributed constellations may be associated with a larger mutual information (e.g., an information I, defined by parameters X and Y) than uniformly distributed constellations, at the same SNR.

An example of a probabilistic shaping framework (e.g., for generating probabilistic shaping 240) may be probabilistic amplitude shaping (PAS) (e.g., distribution matching). PAS may shape an amplitude of a constellation of modulated symbols (e.g., the amplitude may be non-uniform), while leaving the sign of the constellation uniformly distributed. In some examples, PAS may be performed prior to channel coding of information bits. In some examples, PAS may perform shaping on information bits (e.g., shaping the bits for distribution into a non-uniform constellation of symbols), and may utilize systematic channel codes. For example, PAS may use a systematic channel code to preserve the shaping applied to the information bits (e.g., the shaping may be preserved during channel coding, which may occur after shaping). In PAS, parity bits may not be shaped, and instead may be mapped to the signs of the constellations (e.g., which signs may not be shaped in PAS).

PAS may be based on code. In some other examples, PAS may be based on source compression techniques, such as arithmetic coding (e.g., Huffman code). Source coding may convert non-uniformly distributed sources into uniform bits, and PAS may reverse the conversion. Techniques for PAS may include CCDM (constant-composition distribution matching), multi-CCDM (multiple composition distribution matching), sphere shaping (constraining the input codeword (a multi-dimensional complex vector) into a power sphere), etc. However, to apply such schemes to a commination system, the compression of the bits may be specified. For example, the compression algorithm may be specified up to fixed-points, which may be quantized by the probability values of a defined precision. Additionally, specification of the compression algorithm may include different configurations for shaping rate, target prob distribution, block length, modulation order, etc. In some examples, the source code may be non-linear, which may be difficult to jointly design with FEC. Further, hardware and software improvements may be implemented to accommodate high speed compression and decompression.

In some examples, PAS may be based on source code based on a source compression algorithm (e.g., arithmetic coding, Huffman code) to shape the information bits to a given probability distribution, followed by the use of a high rate systematic code to encode the shaped information bits. Using a high rate systematic code may preserve the distribution on the information bits. In some other examples, the PAS may be based on block code (e.g., polar code), which may generate masking bits to mask the information bits to a specific distribution.

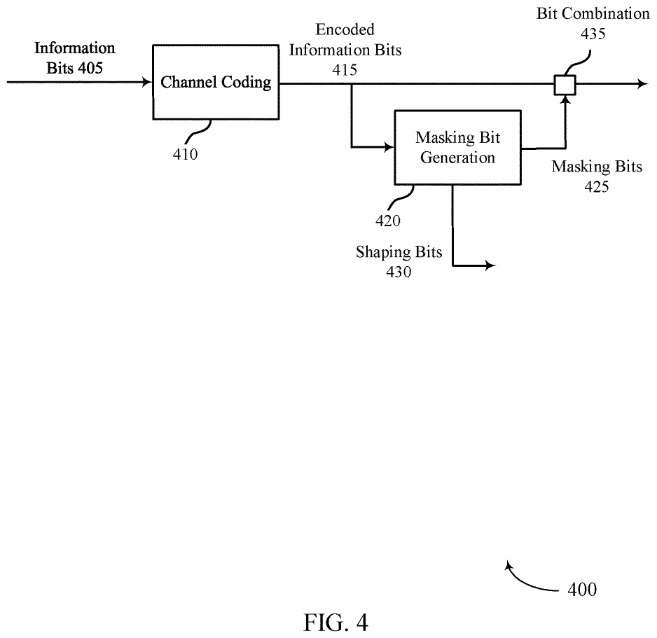

In some examples, polar code may be used for information transmission. A number of binary-input noisy channels (e.g., n i.i.d.) with a capacity (e.g., C∈(0,1), where a fraction of good channels≈C) may be converted into channels by a polarization kernel. The channels may be of varying capability (e.g., lower capacity (capacity≈0), high capacity (capacity≈1)). Thus, the channel is polarized. Polar code may transmit frozen bits (e.g., all zero bits) in the lower channels, an transmit information bits in the higher capacity channels. Channels may be measured in terms of channel capacity (e.g., I(Bᵢ; Yⁿ|B₀ⁱ⁻¹)), where a greater channel capacity indicates a better channel. Polar code may be designed to place frozen bits and information bits into the different channels. The placement, or location, may be referred to as frozen bit location or information bit location. Techniques described herein are directed to a PAS framework based on polar code. Block code may be further described with respect to FIG. 4.

The signaling diagram 300 may implement aspects of the wireless communications system 100 and the wireless communications system 200 or may be implemented by aspects of the wireless communications system 100 and the wireless communications system 200. For example, the signaling diagram 300 may be an example of communications between the wireless devices 205 as described with reference to FIG. 2. The signaling diagram 300 depicts an example of probabilistic shaping, including a probabilistic shaper 310 (e.g., distribution matching) followed by forward error correction (FEC).

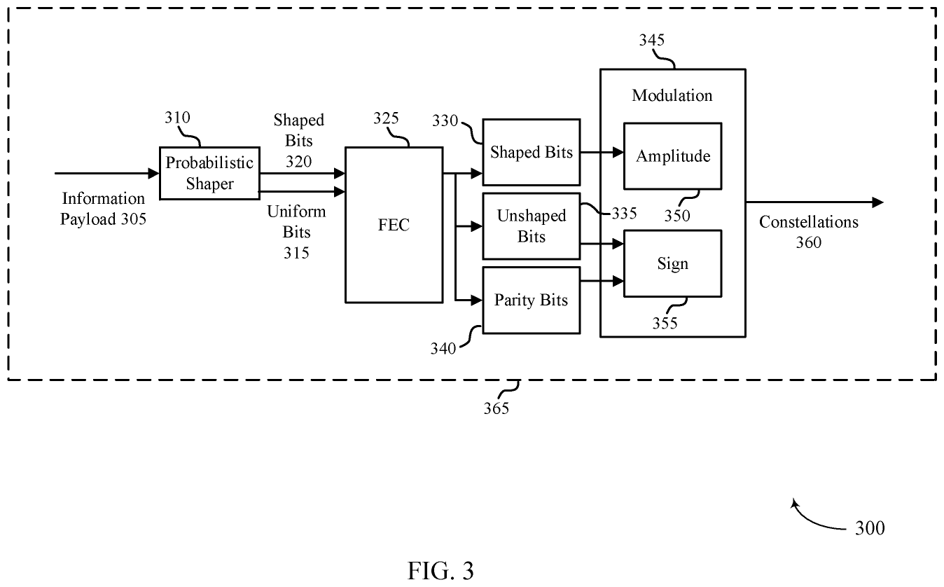

FIG. 3 illustrates an example of a signaling diagram 300 that supports probabilistic shaping based on block codes in accordance with one or more aspects of the present disclosure. The signaling diagram 300 may implement aspects of the wireless communications system 100 and the wireless communications system 200 or may be implemented by aspects of the wireless communications system 100 and the wireless communications system 200. For example, the signaling diagram 300 may be an example of communications between the wireless devices 205 as described with reference to FIG. 2. The signaling diagram 300 depicts an example of probabilistic shaping, including a probabilistic shaper 310 (e.g., distribution matching) followed by forward error correction (FEC). In some examples, a device 365 (e.g., a transmitter) may perform probabilistic shaping according to the signaling diagram 300.

In accordance with probabilistic shaping (such as probabilistic amplitude shaping (PAS)), a transmitting device (such as a wireless device 205) may input an information bits 305 (an information payload, such as a set of input bits associated with a data message) into the probabilistic shaper 310. The probabilistic shaper 310 may output a set of shaped bits 320 and a set of uniform bits 315, and input the two sets of bits into the FEC encoder 325. The probabilistic shaper 310 may transform the information bits 305 (e.g., uniform bits) into non-uniformly distributed bits (e.g., the shaped bits 320) according to a given target probability distribution. The wireless device 205 may additionally input a set of parity bits into the FEC encoder 325 associated with the information payload. In some aspects, the FEC encoder 325 may be a high rate systematic FEC encoder.

The FEC encoder 325 may output a set of shaped bits 330 (e.g., information bits, systematic bits), a set of unshaped bits 335 (e.g., information bits, systematic bits), and a set of parity bits 340 (which also may be unshaped). Constellation mapping 345 may map the set of shaped bits 330, which may be non-uniformly distributed or biased, to an amplitude 350 of one or more constellation points. The constellation mapping 345 may map the set of unshaped bits 335, which may be uniformly distributed or unbiased, and the set of parity bits 340 to a sign 355 of one or more constellation points. As such, for a given constellation point, an amplitude of the constellation point may be shaped while a sign of the constellation point remains unshaped (and associated with a uniform distribution). In some examples, the resulting modulation symbols the constellation mapping 345 may be non-uniformly distributed. In some aspects, the constellation mapping 345 may be associated with a QAM modulation and an output of the QAM modulation may be uniformly distributed QAM constellations 360.

In some examples of techniques described herein, a transmitting device may generate a set of shaped bits (e.g., including shaping bits and information bits), and may transmit a message including the shaped bits to a receiving device.

FIG. 4 illustrates an example of a signaling diagram 400 that supports probabilistic shaping based on block codes in accordance with one or more aspects of the present disclosure. The signaling diagram 400 may implement aspects of the FIGS. 1-3, or may be implemented by aspects of the FIGS. 1-3. FIG. 4 may be an example of one or more features of a framework for probabilistic shaping based on block code and bit masking. For example, a transmitter (e.g., a transmitting wireless device such as a UE 115 or a network entity 105) may encode and transmit a message according to the signaling diagram 400, and may be an example of corresponding devices described with reference to FIGS. 1-3 (e.g., may be a UE 115, a wireless device 205, or a network entity 105). FIG. 4 illustrates one or more techniques for the processing of information bits 405 (e.g., u) for coding, shaping, and combining information bits 305 (e.g., data and associated parity bits) for transmission.

For example, a transmitting device (e.g., a wireless device 205) may directly encode the information bits 405 using a channel coding 410 (e.g., a channel coding scheme). After performing the channel coding 410, the information bits 405 may be referred to as encoded information bits 415 (e.g., x). At the masking bit generation 420, the transmitting device may generate a set of masking bits 425 using the encoded information bits 415, and may also generate a set of shaping bits 430. The set of masking bits 425 may have a same quantity of bits (e.g., n bits) as the encoded information bits, such that the combination (e.g., via a bit-wise XOR operation) of the set of shaping bits and the encoded information bits may not be uniformly distributed (e.g., may achieve the targeted shaped distribution).

For example, after modulation, the masking bits 425 and the encoded information bits 415 may be combined at bit combination 435. The combination of the set of masking bits 425 and the encoded information bits 415 (e.g., x+v) may result in a desired distribution (e.g., non-uniform distribution) of modulated symbols. In some examples, there may be a quantity (e.g., v) of codewords of a block code. In some examples, the masking bit generation 420 may be applied to parity bits associated with data carried by the encoded information bits 315. For example, the encoded information bits 415 may include parity bits associated with data that is included in the encoded information bits 415.

In some examples, information about the set of masking bits 425 may not be available to a receiving device (e.g., a UE 115, a network entity 105). As such, information associated with the set of masking bits 425 may be generated and transmitted to the receiver for deshaping (e.g., de-masking or descrambling) received information bits. For example, the transmitting device may use the set of masking bits 425 to generate a set of shaping bits 430 that may be used for generating a mask (e.g., v, the set of masking bits 425) for masking the encoded information bits 415. In some cases, the transmitting device may use the set of shaping bits 430 to generate the set of masking bits 425. The set of shaping bits 430 may represent a second sequence of bits (e.g., s) that may have a smaller length than v, but may be used to generate v (e.g., the set of masking bits 425). For example, the shaping bits 430 may be generated by compressing the set of masking bits 425, such that the masking bits 425 may be equal to the shaping bits 430 multiplied by a generator matrix (e.g., G). In some examples, the masking bits 425 may be generated (e.g., re-generated by the receiving device, generated by the transmitting device) from the shaping bits 430 via a linear block code (e.g., Golay code, polar code, LDPC code, convolutional code, Turbo code, Reed Muller code) using a generator matrix (e.g., G). For example, the linear block code may be applied to the shaping bits 430 by multiplying the shaping bits 430 by a generator matrix (e.g., which generator matrix may be associated with or configured for application of the linear block code).

As described herein with respect to FIG. 4, the technique of probabilistic shaping based on block code and bit masking generation 420 does not include specifying an additional source coding algorithm. The technique does not include specifying the code (such as polar code, or another linear code), such that the detailed shaping algorithm may be implemented according to specifications, similarly to a channel decoder. However, such a technique generates a set of shaping bits 430, which may be compressed version of the masking bits 425 (e.g., v), that may be conveyed to the receiver. The shaping bits 430 may be conveyed using the same communicational channel as data, which may allow for the receiver to recover the masking bits 425. In such examples, the shaping bits 430 are unshaped and the information bits are shaped. For examples, if the shaping rate is 0.7 (according to the equation K_{info}/(K_{info}+Kₛₕₐₚₑ)), then the quantity of shaping bits 430 to be generated (e.g., Kₛₕₐₚₑ) may be 75% of the number of information bits 405, and the shaping bits 430 may not be shaped.

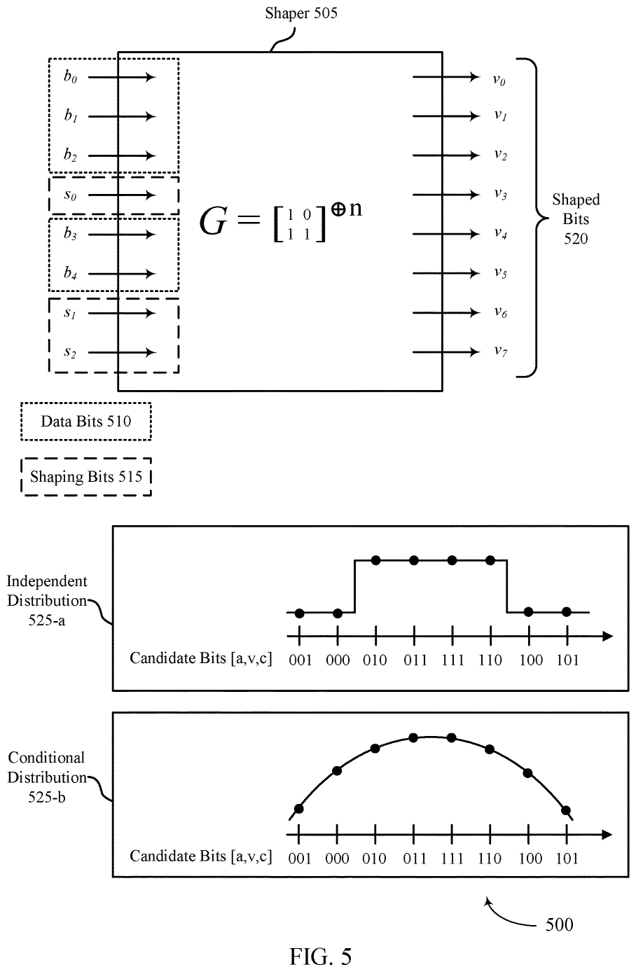

FIG. 5 illustrates an example of a shaping scheme 500 that supports probabilistic shaping based on block codes in accordance with one or more aspects of the present disclosure. Shaping scheme 500 may implement, or be implemented by, aspects of wireless communications system 100 and wireless communications system 200. For example, a transmitter (e.g., a transmitting wireless device such as a UE 115 or a network entity 105) may encode and transmit a message according to the shaping scheme 500, and may be an example of corresponding devices described with reference to FIGS. 1-4 (e.g., may be a UE 115 or a network entity 105).

Techniques described herein support shaping and encoding procedures resulting in improved throughput and increased reliability of transmissions. A transmitter may use a shaper 505 to shape one or more data bits 510 (e.g., information bits), such as a set of K data bits b (e.g., [b₀, . . . , b_{K-1}]), and one or more shaping bits 515, such as a set of L shaping bits s (e.g., [s₀, . . . , s_{L-1}]), resulting in a set of shaped bits 520, such as a set of N shaped bits v (e.g., [v₀, . . . , v_{N-1}]). In some examples, the procedure of multiplying a set of bits by a matrix G (e.g., using the shaper 505) may be referred to as a polar transform, or applying a polar transform to the set of bits. In some examples, a polar transform may be implemented via a fast Hadamard transform.

In some examples, the transmitter may use a block code (e.g., a polar code), and a target probability distribution on the coded bits. For example, the transmitter may use the block encoder (e.g., a block code) to encode the data bits 510 and the shaping bits 515 into a set of block encoded (e.g., polar coded) bits such that the data bits (e.g., [b₀, . . . , b_{K-1}]) are placed at the frozen bit locations of the polar code, the shaping bits (e.g., [s₀, . . . , s_{L-1}]) are placed at the information bit locations of the polar code, and the encoded bits or shaped bits 520 (e.g., [v₀, . . . , v_{L-1}]) from the polar encoder have the desired target probability distribution. In some examples, techniques described herein with reference to FIGS. 5-10 may be implemented with any block code, channel code, linear code, etc. For example, the techniques described herein may be implemented using low-density generator matrix (LDGM) code, convolution codes, turbo codes, Reede Muller codes, or algebraic codes (e.g., Bose-Chaudhuri-Hocquenghem (BCH), Reed Solomon, or Hamming codes, etc.), among other examples.

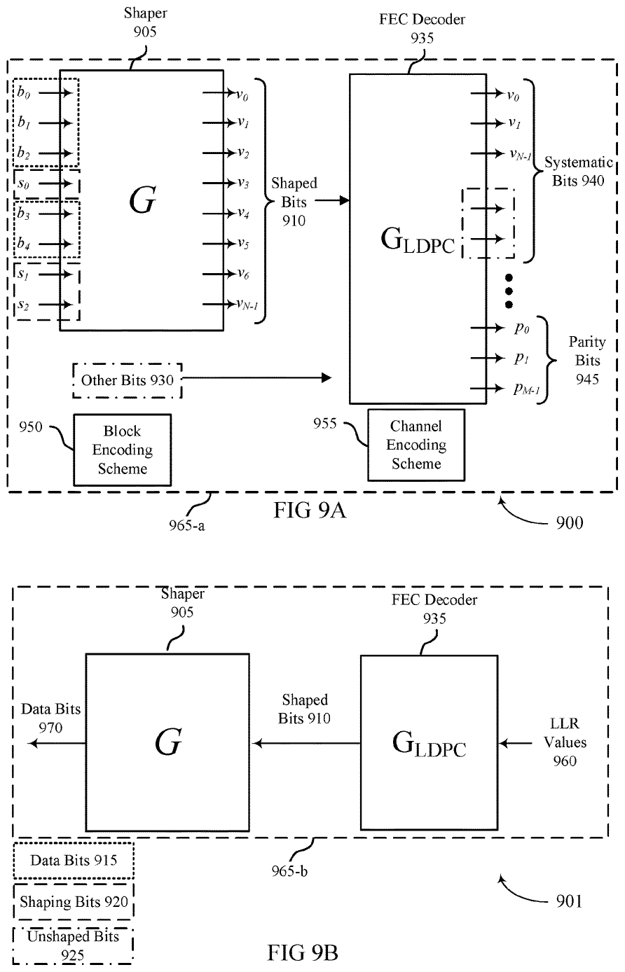

The transmitter may determine the set of shaping bits 515 (e.g., [s₀, . . . , s_{L-1}]) based on the data bits 510, and using the polar decoder. The shaping bits 515 may be obtained from a function (e.g., a deterministic function) of the data bits. In some examples, the shaping bits 515 or the shaped bits 520 may contain zero new information conditioned on all other data bits 510. For example, a condition entropy of the shaped bits 520 or the shaping bits 515 for given data bits 510 may be zero. The data bits 510 may include data bits to be shaped (e.g., [b₀, . . . , b_{K-1}]), and may further include other data bits that are not to be shaped (e.g., as described in greater detail with reference to FIG. 9A).

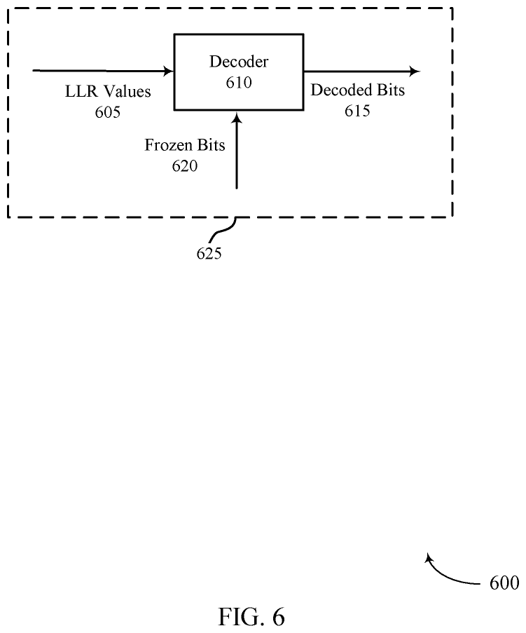

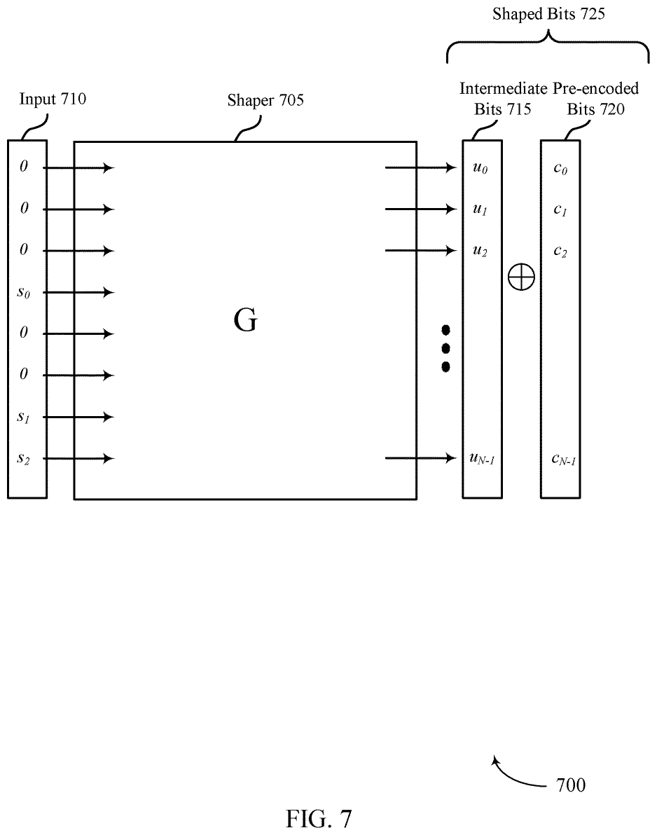

In some examples, as described in greater detail with reference to FIGS. 6-7, the transmitter may determine the shaping bits 515 based on a set of LLR values. In some cases, the transmitter may calculate the LLR values based on data (e.g., the data bits 510). The shaped bits 520 may be based on the target distribution, and may all be passed to a same bit-location of a modulation symbol. For instance (e.g., in an 8 Pam system, such as a 64 QAM system), the transmitter may map three bits (e.g., [a, v, c]) to a modulation symbol. The transmitting may map the bits [a, v, c] according to a shaping scheme (e.g., independent distribution 525-a, which may be referred to as an unconditional shaping) or according to a different shaping scheme (e.g., a conditional distribution 525-b). In some examples, the transmitter may map the bits a, v, and c according to the target distribution using a uniformly distributed shaping, and v may represent the bit that is to be shaped, such as a candidate shaped bit (e.g., a candidate bit a, v, or c). The transmitter may first determine a conditional distribution (e.g., Pr(v=0|c) based on the target distribution. The LLR of each bit vᵢ may be determined from the other data bits to be mapped to the same modulation symbol (e.g., bits c), and the target conditional distribution Pr(v|c) may be defined or determined such that

$$LLR ( {v}_{i} ) = log \frac{Pr ( {v}_{i} = 0 \vert {c}_{i} )}{Pr ( {v}_{i} = 1 \vert {c}_{i} )} .$$

In such cases, the shaping may be conditional distribution 525-b (e.g., the LLR of each bit v is determined from the other data bits being mapped to the same modulation symbol). In some examples, v may be independent from the 3 other bits a and c mapped to the same modulation symbol, in which case the LLR may be simplified such that

$$LLR ( {v}_{i} ) = log \frac{Pr ( {v}_{i} \vert {c}_{i} )}{Pr ( {v}_{i} \vert {c}_{i} )} .$$

In such cases, the shaping may be unconditional or independent distributed 525-a (e.g., the LLR of each bit v is independent from the other bits mapped to the same modulation symbol). If the transmitter shapes both v and one or more additional bits c, then the transmitter may first perform shaping (e.g., via the shaper 505) according to Pr(v) using one shaping code, and may then shape c according to Pr(c) using a second shaping code.

A receiving device may receive and decode a transmission generated according to techniques described herein (e.g., with reference to FIG. 5). For example, the receiver may obtain shaped bits v (e.g., shaped bits 520). The receiver may apply a polar transform (e.g., may multiple the vector of bits v by the same matrix G, which may be an NXN matrix) to obtain a set of data bits b (e.g., data bits 510) and shaping bits s (e.g. shaping bits 515). The receiver may extract the data bits b from the frozen bit locations of the corresponding polar code, and the shaping bits s may be discarded (e.g., because they do not contain any useful information corresponding to the data).

In some examples, as described in greater detail with reference to FIG. 6, the transmitter may generate the shaping bits based on the LLR values.

FIG. 6 illustrates an example of a bit generation scheme 600 that supports probabilistic shaping based on block codes in accordance with one or more aspects of the present disclosure. Bit generation scheme 500 may implement, or be implemented by, aspects of wireless communications system 100 and wireless communications system 200. For example, a device 625 (e.g., a transmitting wireless device such as a UE 115 or a network entity 105) may encode and transmit a message according to the bit generation scheme 500, and may be an example of corresponding devices described with reference to FIGS. 1-5 (e.g., may be a UE 115 or a network entity 105).

The transmitter may encode and transmit a message according to techniques described herein. The transmitter may generate shaping bits based on a set of LLR values (e.g., as described with reference to FIG. 5). In some examples, a decoder 610 (e.g., a polar decoder) may be used for encoding and decoding wireless signaling. For example, the polar decoder 610 may obtain LLR values 605 (e.g., from a channel output), and may obtain frozen bits 620, which the transmitter may set to all zero values, resulting in an output of decoded bits 615 (e.g., decoded information bits). However, such techniques may result in decreased throughput and increased latency on the receiver side (e.g., due to the receiver decoding shaped bits and additional data bits). Techniques described herein may support generation of shaped bits (e.g., without the need for additional decoding of shaped bits and data or information bits).

For example, according to techniques described herein, the transmitter may obtain LLR values based on a target distribution, other non-data bits, or both. The transmitter may decode the LLR values using the decoder 610 (e.g., a polar decoder). The decoder 610 may also fill the frozen bits of the polar code with the data bits, instead of with all zero bits. The decoder 610 may be able to determine the set of shaping bits from the LLR values (e.g., the decoded bits 615 are shaping bits), and the shaping bits may correspond to information bits associated with the decoder 610.

FIG. 7 illustrates an example of a shaping scheme 700 that supports probabilistic shaping based on block codes in accordance with one or more aspects of the present disclosure. Shaping scheme 700 may implement, or be implemented by, aspects of wireless communications system 100 and wireless communications system 200. For example, a transmitter (e.g., a transmitting wireless device such as a UE 115 or a network entity 105) may encode and transmit a message according to the shaping scheme 700, and may be an example of corresponding devices described with reference to FIGS. 1-6 (e.g., may be a UE 115 or a network entity 105).

In some examples, the transmitter may generate a set of shaping bits s (e.g., [s₀, . . . , s_{L-1}]) such that sG+b confirms to (e.g., obeys) the target probabilistic distribution, where s denotes a length-K data vector that includes all zero frozen bits and the shaping bits, and b denotes the length-K data vectors to be shaped, and G denotes a generation matrix. In such examples, the size of the generator matrix G may be K×K.

In some examples, according to techniques described herein, shaping may be applied to block encoded data (e.g., polar encoded data such as shaped bits 520) such that c=bG, where b denotes the length-N vector that includes data bits (e.g., [b₀, . . . , b_{K-1}]), on the frozen bit locations, and all zero bits on the information bit locations of the block code (e.g., a polar code), and G denotes a generation matrix. In such examples, the size of the generator matrix G may be N×N. Thus, the transmitter may pre-encode the data using a block code (e.g., polar coding) by putting the data bits on the frozen-bit locations, and adding zeros in the information bit locations. The input 710 may thus include the data bits on the frozen-bit locations, and the zeros in the information bit location.

The shaper 705 may generate shaped bits 725 (e.g., shaped bits v, where v=u+c) according to the generation matrix G, and the pre-encoded bits 720 (e.g., [c₀, . . . , c_{N-1}]) may be defined as c=bG (e.g., where an equivalence can be shown via linearity of G, such that (s+b)G=sG+bG, where b represents data bits, s represents the shaping bits, and v represents the shaped bits, where v=u+c). In some examples, the size of the matrix G may be defined as K×K, where K denotes a number of data bits before shaping. In some examples, as described herein, the size of the matrix G may be defined is N×N, where N denotes the length of the information bits after shaping (e.g., the shaped bits may include both unshaped data bits and shaping bits). In examples where the size of the matrix G is K×K, the shaping bits may be transmitted separately to the receiver for the receiver to be able to decode the data bits b. But in the second approach, information about the shaping bits may be contained in the shaped bits (e.g., such that is u+c=(s+b)G), and therefore there is no need to separately convey the information about shaping bits s to the receiver.

Such techniques may result in reduced processing on the receiver side, decreased signaling overhead, more efficient utilization of communication resources, and improved reliability of wireless signaling. For example, some shaping and transmission techniques (e.g., as described in some aspects of FIG. 5) may include putting data bits in the frozen bit locations, and use a decoder to generate the shaped bits directly. However, such procedures may include changing an existing polar decoder (e.g., by replacing frozen bits to data bits). Such procedures may be costly because the frozen bits may be hardcoded to be all zero, and to change these bits to non-zero values (e.g., contrary to the hard coding of the device hardware), modifications to the existing decoding implementation may be needed to change these bits from all-zero frozen bits to non-zero data bits (e.g., may result in increased expenditure of power and processing resources, increased processing delays, etc.).

In some examples, as described with reference to FIG. 7, the transmitting wireless device may use its polar decoder by keeping the frozen bits to all zero, hence the existing polar decoder can be reused (e.g., without changes). In such techniques, the decoder may output some intermediate bits (e.g., u), and to generate the final shaped bits 725 (e.g., v), the transmitter device may add the pre-encoded data bits 720 (e.g., c=bG) to the intermediate bits u. Such techniques may be relatively easier to implement by the transmitting device, because such techniques may be implemented using the existing encoder.

Overall, techniques described with reference to FIG. 5 and techniques described with reference to FIG. 7 may be result in a similar set of shaped bits. But approach described with reference to FIG. 7 may be simpler to implement if the device has already implemented a polar decoder/encoder for communication purposes (e.g., to communicate control signals).

A receiving device may receive and decode a transmission generated according to techniques described herein (e.g., with reference to FIG. 7). For example, the receiver may obtain shaped bits v (e.g., shaped bits 725). The receiver may apply a polar transform (e.g., may multiple the vector of bits v by the same matrix G, which may be an N×N matrix) to obtain a set of data bits b and shaping bits s. The receiver may extract the data bits b from the frozen bit locations of the corresponding polar code, and the shaping bits s may be discarded (e.g., because they do not contain any useful information corresponding to the data).

The transmitter may calculate LLR values based on the data as described in greater detail with reference to FIG. 6. In some examples, the transmitter may shape parity bits according to a joint design with a FEC.

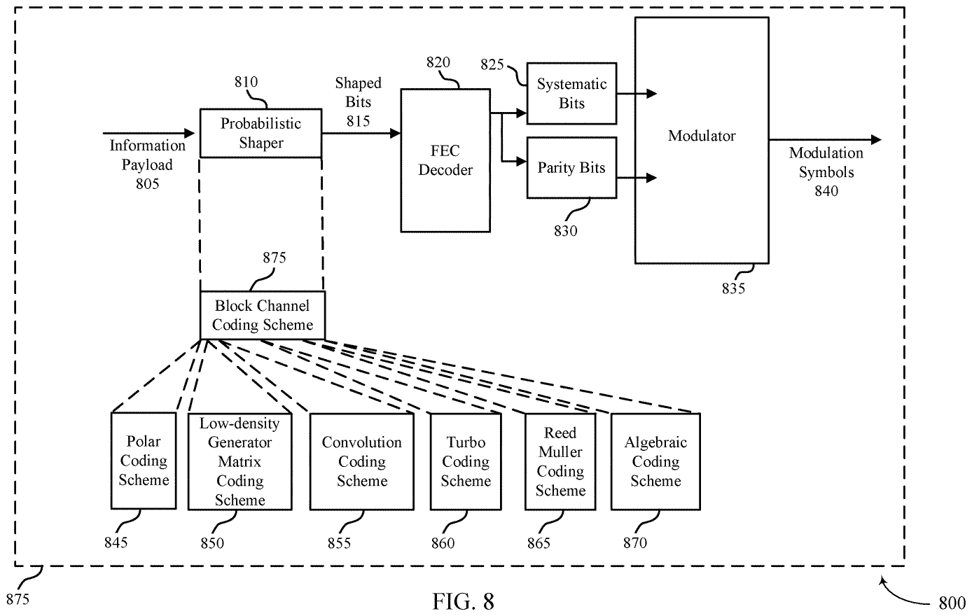

FIG. 8 illustrates an example of an encoding scheme 800 that supports probabilistic shaping based on block codes in accordance with one or more aspects of the present disclosure. The encoding scheme may be implemented by or may implement aspects of wireless communications system 100 and wireless communications system 200 (e.g., may be performed by a transmitting device such as the device 875). The transmitting device may include a probabilistic shaper 810, which may obtain information payload 805, and may output shaped bits 815 as described in greater detail with reference to FIGS. 4-7. The transmitting device may perform encoding procedures (e.g., may generate shaped bits 815) using the probabilistic shaper 810. In some examples, the transmitting device may generate the shaped bits 815 using a block channel coding scheme 875. In some examples, the block channel encoding scheme 875 may be a polar encoding scheme 845, an LDGM encoding scheme 850, a convolution encoding scheme 855, a turbo code encoding scheme 860, a Reed Muller encoding scheme 865, or an algebraic encoding scheme 870 (e.g., BCH, Reed Solomon, or Hamming codes, etc.).

In some examples, the techniques described herein may support a shaping design that is based at least in part on (e.g., takes into account) a channel code or FEC (e.g., an LDPC) used by the transmitter. This may result in shaping the parity bits 830 of the FEC decoder 820, in addition to the systematic bits 825. For example, the FEC decoder 820 may obtain the shaped bits 815 as an input, and may output systematic bits 825 and parity bits 830, and may then perform modulation (e.g., at the modulator 835) on the systematic bits 825 and the parity bits 830, generating modulation symbols 840 (e.g., non-uniformly distributed modulation symbols). Such techniques may support joint use of a decoder that decodes the FEC decoder 820 and the block code (e.g., polar code) used in the probabilistic shaper. Such techniques are described in greater detail with reference to FIGS. 9A and 9B.

FIG. 9A and FIG. 9B illustrate examples of a shaping scheme 900 and shaping scheme 901 that supports probabilistic shaping based on block codes in accordance with one or more aspects of the present disclosure. Shaping schemes 900 and 901 may implement, or be implemented by, aspects of wireless communications system 100 and wireless communications system 200. For example, a device 965-a (e.g., a transmitting wireless device such as a UE 115 or a network entity 105) may encode and transmit a message according to the shaping scheme 900, or a device 965-b (e.g., a receiving deice such as a UE 115 or network entity 105) may receive and decode a message according to the shaping scheme 901, and may be an example of corresponding devices described with reference to FIGS. 1-8 (e.g., may be a UE 115 or a network entity 105).

The transmitter may use the FEC decoder 935 to compute LLR values to be fed to the decoder of the probabilistic shaper. In some examples, the transmitter may prepare a first set of LLR values for the FEC decoder 935 using techniques outlined with reference to FIGS. 6-7 for bits that the transmitter will shape (e.g., including shaped information bits 910 and party bits 945 (e.g., a set of M parity bits p, where [p₀, . . . , p_{M-1}]). In cases where information bits are not to be shaped are input into the FEC decoder 935, the transmitter may set the LLR values for such bits to positive infinity or negative infinity (e.g., where infinity may simply represent a very large number).

For example, the shaper 905 may shape one or more data bits 915 and one or more shaping bits 920, resulting in shaped bits 910 (e.g., according to shaping matrix

$$G = {[ \begin{matrix}1 & 0 \\ 1 & 1\end{matrix} ]}^{⊗ n} ) .$$

In some examples, the shaped bits 910, and other bits 930 (e.g., non-shaped bits) may be input into the FEC decoder 935, which may generate systematic bits 940 (e.g., which may include unshaped bits 925 and additionally shaped bits), and parity bits 945. In some examples, the other bits 930 may include other information bits that are not shaped (e.g., may be included as part of, or may include, unshaped bits 925).

Such techniques may run the FEC decoder 935 to compute a new set of LLR values (e.g., LLRₚₒₛₜ(vᵢ)), and may use the new set of LLR values in the shaper to do the shaping. The posterior LLR values (e.g., LLRₚₒₛₜ(vᵢ)) may take into account the desired probability distribution on systematic bits 940 and parity bits 945. In some examples, the transmitting device may apply a block encoding scheme 950 and a channel encoding scheme 955. For example, the shaped bits may include the information bits and the shaping bits, and a set of parity bits associated with the FEC decoder 935 (e.g., the channel encoding scheme 955). The transmitter may identify the channel encoding scheme 955 to encode the shaped bits 910 (e.g., including the data bits 915 and the shaping bits 920) to generate the set of parity bits 945. The transmitter may determine the shaping bits 920 using a joint decoder of the block encoding scheme 950 and the channel encoding scheme 955, and based on the target probability distribution of the shaped bits 910 and a second target probability distribution of the shaped parity bits 945 (e.g., and the first and second target probability distributions may be the same, or may be different). In such examples, the transmitting device may apply the channel encoding scheme 955 to the shaped bits 910 to generate the parity bits 945, and the selection of the shaping bits 920 may be performed such that the resulting parity bits 945 are also shaped according to the target probability distribution (e.g., or the second target probability distribution). Some techniques (e.g., as described with reference to FIGS. 5-7) may not take into account a distribution of the parity bits 945 in the LLR generation for a decoder corresponding to a shaping code. As a result, generated parity bits 945 from an LDPC/channel encoder may be uniformly distributed.

In some examples, a wireless device may receive a message according to shaping scheme 901. For example, the receiving device may receive a message, and determine one or more LLR values 960 corresponding to shaped info bits, unshaped info bits, shaped parity bits, unshaped parity bits, or any combination thereof (e.g., systemic bits 940, and parity bits 945). The LLR values 950 may be fed to an FEC decoder 935. The FEC decoder 935 may output the shaped bits 910, which may be fed to the shaper 905 (e.g., a polar decoder). The Shaper 905 may generate an output including data bits 970 (e.g., shaping bits, and info bits).

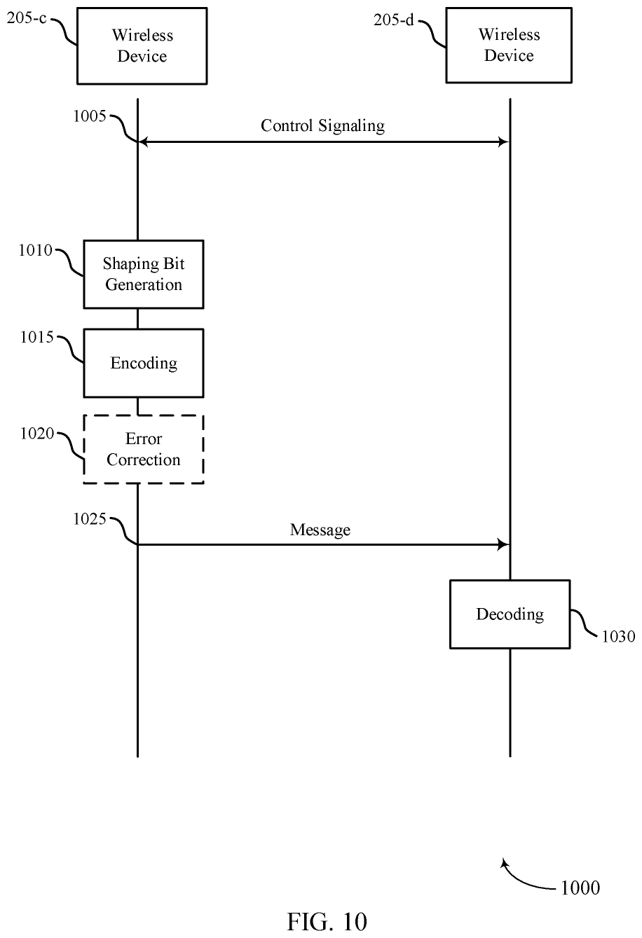

FIG. 10 illustrates an example of a process flow 1000 that supports probabilistic shaping based on block codes in accordance with one or more aspects of the present disclosure. In the following description of the process flow 1000, the operations between the wireless device 205-c and the wireless device 205-d may be performed in different orders or at different times. Some operations may also be left out of the process flow 1000, or other operations may be added. Although the wireless device 205-c and the wireless device 205-d are shown performing the operations of the process flow 1000, some aspects of some operations may also be performed by one or more other wireless devices.

At 1005, the wireless device 205-c and the wireless device 205-d may communicate control signaling. The wireless device 205-c may determine the block encoding scheme associated with the target probability distribution for transmission of the message based on the control signaling, or autonomously. The block encoding scheme may be one of a polar coding scheme, a low-density generator matrix coding scheme, a convolution coding scheme, a turbo coding scheme, a Reed Muller coding scheme, an algebraic coding scheme, or any combination thereof. The wireless device 205-c may communicate control signaling indicating the block encoding scheme, and the determining may be based on the control signaling.

The wireless device 205-d may determine a block encoding scheme, which may be associated with the target probability distribution for reception of the message. The wireless device 205-d may communicate, with the wireless device 205-d, control signaling scheduling a transmission of the message and indicating the block encoding scheme, and may determine the block encoding scheme based on communicating the control signaling.

The wireless device 205-c may determine a mapping of multiple information bits to multiple frozen bit locations and the multiple shaping bits to multiple information bit locations, and may then encode and transmit the message based on the mapping. The wireless device 205-c may communicate control signaling indicating the mapping, where the determining is based on communicating the control signaling.

In some examples, the control signaling may indicate a target probability distribution for the message, may indicate the message is generated using a channel coding scheme and the block encoding scheme, or a may indicate a combination thereof.

At 1010, the wireless device 205-c (e.g., a first device) may generate multiple shaping bits. The shaping bit generation may be based on multiple information bits, and the multiple shaping bits may be associated with the shaping of the multiple information bits into (e.g., according to) a target probability distribution associated with a block encoding scheme. Generating the shaping bits may include calculating a set of LLR values based on the target probability distribution and decoding the set of LLR values according to a decoding operation associated with the block encoding scheme to generate the multiple shaping bits. In some examples, the multiple information bits may be mapped to multiple frozen bit locations of the block encoding scheme, and the multiple shaping bits may be based on the set of decoded LLR values.

Calculating the set of LLR values may include mapping a second set of multiple information bits and at least one candidate shaped bit to a modulation symbol. In some examples, calculating may include determining a conditional distribution based on the target probability distribution and determining a LLR value for the at least one candidate shaped bit based on the second set of multiple information bits and the conditional distribution associated with the modulation symbol, where calculating the set of LLR values is based on determining the LLR value for the at least one candidate shaped bit. In some examples, the second set of multiple information bits may be independently distributed from distribution of the multiple shaped bits according to the encoding, and shaping the second set of multiple information bits according to the encoding.

At 1015, the wireless device 205-c may encode the multiple information bits and the multiple shaping bits according to the block encoding scheme to generate multiple shaped bits satisfying the target probability distribution. The wireless device 205-c may generate the multiple shaped bits using a joint decoder for the block encoding scheme and a channel encoding scheme based at least in part on the target probability distribution associated with the block encoding scheme and a second target probability distribution associated with the channel encoding scheme. The wireless device 205-c may apply a channel encoding scheme to the multiple shaped bits including the multiple information bits and the multiple shaping bits to generate multiple parity.

The encoding may include calculating a first set of LLR values for the block encoding scheme based on the target probability distribution, and calculating a second set of LLR values for the channel encoding scheme for the decoder (e.g., at 1020, the wireless device 205-c may perform error correction according to a channel encoding scheme associated with an FEC decoder) associated with the channel encoding scheme. The second set of LLR values may be based on the second target probability distribution corresponding to the multiple parity bits, where shaping the multiple shaped bits is based on the first set of LLR values and the second set of LLR values.

At 1025, the wireless device 205-c (e.g., the first device) may output a message based on the multiple shaped bits. The wireless device 205-d (e.g., the second device) may obtain the message from the wireless device 205-c.

At 1030, the wireless device 205-d may decode the message to generate multiple shaped bits satisfying a target probability distribution associated with a block encoding scheme, the multiple shaped bits including multiple information bits and multiple shaping bits. The wireless device 205-d may jointly decode the multiple shaping bits including the multiple information bits and a second set of multiple information bits. The information bits and second set of information bits may be decoded according to a forward error correction decoder associated with a channel encoding scheme and the block encoding scheme. In such examples, the multiple shaped bits may include multiple parity bits associated with the channel encoding scheme.

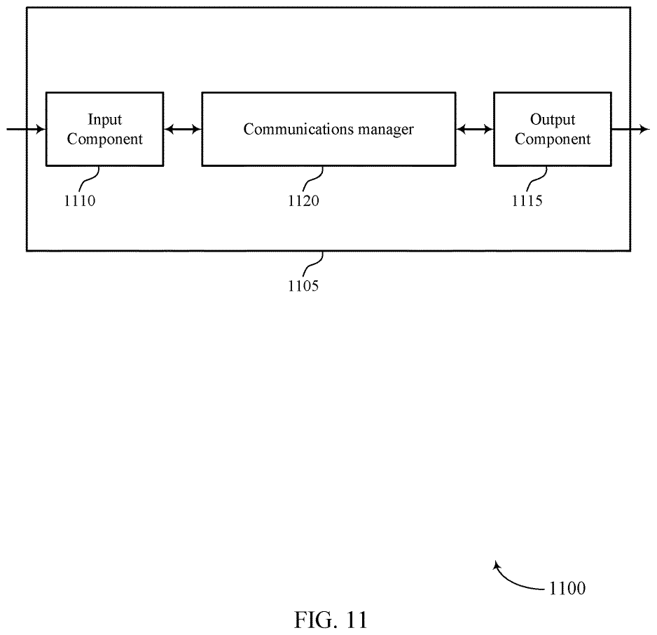

FIG. 11 illustrates a block diagram 1100 of a device 1105 that supports probabilistic shaping based on block codes in accordance with one or more aspects of the present disclosure. The device 1105 may be an example of aspects of a Generic Device as described herein. The device 1105 may include an input component 1110, an output component 1115, and a communications manager 1120. The device 1105 may also include a processor. Each of these components may be in communication with one another (e.g., via one or more buses).

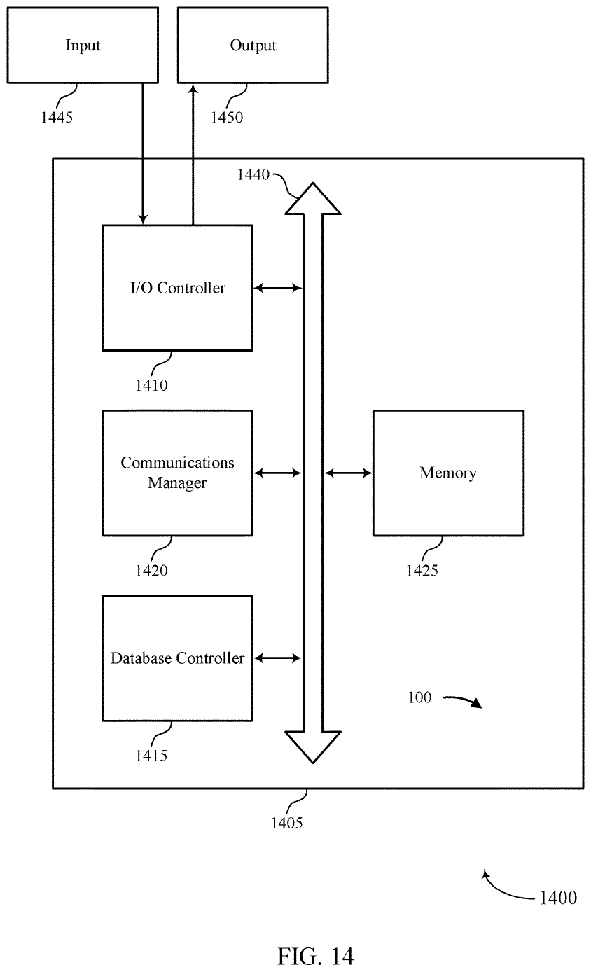

The input component 1110 may manage input signals for the device 1105. For example, the input component 1110 may identify input signals based on an interaction with a modem, a keyboard, a mouse, a touchscreen, or a similar device. These input signals may be associated with user input or processing at other components or devices. In some cases, the input component 1110 may utilize an operating system such as iOS®, ANDROID®, MS-DOS®, MS-WINDOWS®, OS/2®, UNIX®, LINUX®, or another known operating system to handle input signals. The input component 1110 may send aspects of these input signals to other components of the device 1105 for processing. For example, the input component 1110 may transmit input signals to the communications manager 1120 to support probabilistic shaping based on block codes. In some cases, the input component 1110 may be a component of an I/O controller 1410 as described with reference to FIG. 14.

The output component 1115 may manage output signals for the device 1105. For example, the output component 1115 may receive signals from other components of the device 1105, such as the communications manager 1120, and may transmit these signals to other components or devices. In some specific examples, the output component 1115 may transmit output signals for display in a user interface, for storage in a database or data store, for further processing at a server or server cluster, or for any other processes at any number of devices or systems. In some cases, the output component 1115 may be a component of an I/O controller 1410 as described with reference to FIG. 14.

The communications manager 1120, the input component 1110, the output component 1115, or various combinations thereof or various components thereof may be examples of means for performing various aspects of probabilistic shaping based on block codes as described herein. For example, the communications manager 1120, the input component 1110, the output component 1115, or various combinations or components thereof may support a method for performing one or more of the functions described herein.

In some examples, the communications manager 1120, the input component 1110, the output component 1115, or various combinations or components thereof may be implemented in hardware (e.g., in communications management circuitry). The hardware may include a processor, a DSP, a CPU, an ASIC, an FPGA or other programmable logic device, a microcontroller, discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally, or alternatively, in some examples, the communications manager 1120, the input component 1110, the output component 1115, or various combinations or components thereof may be implemented in code (e.g., as communications management software or firmware) executed by a processor. If implemented in code executed by a processor, the functions of the communications manager 1120, the input component 1110, the output component 1115, or various combinations or components thereof may be performed by a general-purpose processor, a DSP, a CPU, an ASIC, an FPGA, a microcontroller, or any combination of these or other programmable logic devices (e.g., configured as or otherwise supporting a means for performing the functions described in the present disclosure).

In some examples, the communications manager 1120 may be configured to perform various operations (e.g., receiving, obtaining, monitoring, outputting, transmitting) using or otherwise in cooperation with the input component 1110, the output component 1115, or both. For example, the communications manager 1120 may receive information from the input component 1110, send information to the output component 1115, or be integrated in combination with the input component 1110, the output component 1115, or both to obtain information, output information, or perform various other operations as described herein.

The communications manager 1120 may support wireless communications at a first device in accordance with examples as disclosed herein. For example, the communications manager 1120 may be configured as or otherwise support a means for generating, based on a set of multiple information bits, a set of multiple shaping bits associated with shaping the set of multiple information bits into a target probability distribution associated with a block encoding scheme. The communications manager 1120 may be configured as or otherwise support a means for encoding the set of multiple information bits and the set of multiple shaping bits according to the block encoding scheme to generate a set of multiple shaped bits satisfying the target probability distribution. The communications manager 1120 may be configured as or otherwise support a means for outputting a message that is based on the set of multiple shaped bits.

Additionally, or alternatively, the communications manager 1120 may support wireless communications in accordance with examples as disclosed herein. For example, the communications manager 1120 may be configured as or otherwise support a means for obtaining, from a first device by a second device, a message. The communications manager 1120 may be configured as or otherwise support a means for decoding the message to generate a set of multiple shaped bits satisfying a target probability distribution associated with a block encoding scheme, the set of multiple shaped bits including a set of multiple information bits and a set of multiple shaping bits.

By including or configuring the communications manager 1120 in accordance with examples as described herein, the device 1105 (e.g., a processor controlling or otherwise coupled with the input component 1110, the output component 1115, the communications manager 1120, or a combination thereof) may support techniques for shaping and transmitting information bits and shaping bits, resulting in reduced processing on the receiver side, decreased signaling overhead, more efficient utilization of communication resources, and improved reliability of wireless signaling.

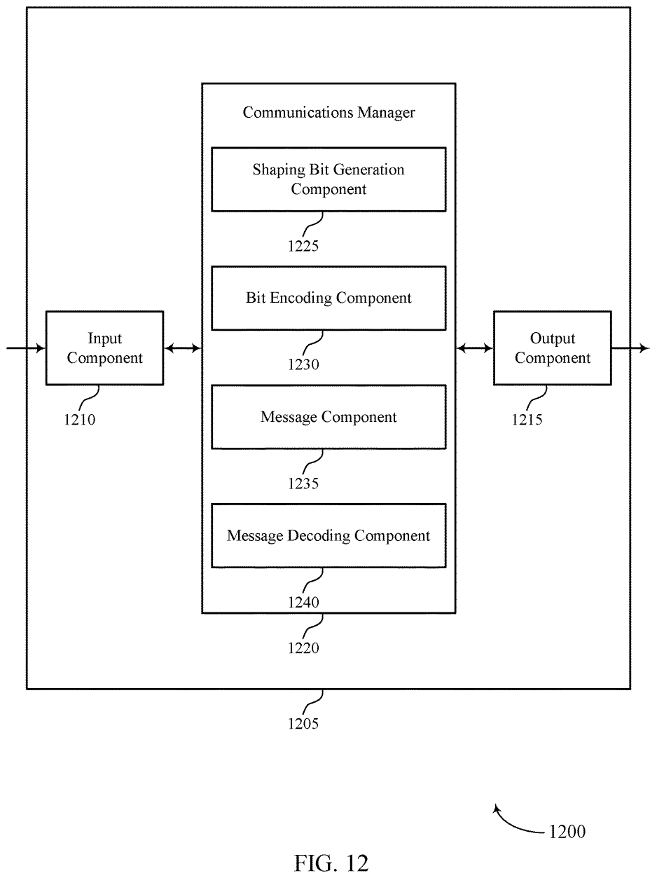

FIG. 12 illustrates a block diagram 1200 of a device 1205 that supports probabilistic shaping based on block codes in accordance with one or more aspects of the present disclosure. The device 1205 may be an example of aspects of a device 1105 as described herein, such as a transmitting device or a receiving device. The device 1205 may be an example of a network entity 105, or a UE 115. The device 1205 may include an input component 1210 (e.g., a receiver), an output component 1215 (e.g., a transmitter), and a communications manager 1220. The device 1205 may also include a processor. Each of these components may be in communication with one another (e.g., via one or more buses).

The input component 1210 may manage input signals for the device 1205. For example, the input component 1210 may identify input signals based on an interaction with a modem, a keyboard, a mouse, a touchscreen, or a similar device. These input signals may be associated with user input or processing at other components or devices. In some cases, the input component 1210 may utilize an operating system such as iOS®, ANDROID®, MS-DOS®, MS-WINDOWS®, OS/2®, UNIX®, LINUX®, or another known operating system to handle input signals. The input component 1210 may send aspects of these input signals to other components of the device 1205 for processing. For example, the input component 1210 may transmit input signals to the communications manager 1220 to support probabilistic shaping based on block codes. In some cases, the input component 1210 may be a component of an I/O controller 1410 as described with reference to FIG. 14.

The output component 1215 may manage output signals for the device 1205. For example, the output component 1215 may receive signals from other components of the device 1205, such as the communications manager 1220, and may transmit these signals to other components or devices. In some specific examples, the output component 1215 may transmit output signals for display in a user interface, for storage in a database or data store, for further processing at a server or server cluster, or for any other processes at any number of devices or systems. In some cases, the output component 1215 may be a component of an I/O controller 1410 as described with reference to FIG. 14.

The device 1205, or various components thereof, may be an example of means for performing various aspects of probabilistic shaping based on block codes as described herein. For example, the communications manager 1220 may include a shaping bit generation component 1225, a bit encoding component 1230, a message component 1235, a message decoding component 1240, or any combination thereof. The communications manager 1220 may be an example of aspects of a communications manager 1120 as described herein. In some examples, the communications manager 1220, or various components thereof, may be configured to perform various operations (e.g., receiving, obtaining, monitoring, outputting, transmitting) using or otherwise in cooperation with the input component 1210, the output component 1215, or both. For example, the communications manager 1220 may receive information from the input component 1210, send information to the output component 1215, or be integrated in combination with the input component 1210, the output component 1215, or both to obtain information, output information, or perform various other operations as described herein.

The communications manager 1220 may support wireless communications at a first device in accordance with examples as disclosed herein. The shaping bit generation component 1225 may be configured as or otherwise support a means for generating, based on a set of multiple information bits, a set of multiple shaping bits associated with shaping the set of multiple information bits into a target probability distribution associated with a block encoding scheme. The bit encoding component 1230 may be configured as or otherwise support a means for encoding the set of multiple information bits and the set of multiple shaping bits according to the block encoding scheme to generate a set of multiple shaped bits satisfying the target probability distribution. The message component 1235 may be configured as or otherwise support a means for outputting a message that is based on the set of multiple shaped bits.

Additionally, or alternatively, the communications manager 1220 may support wireless communications in accordance with examples as disclosed herein. The message component 1235 may be configured as or otherwise support a means for obtaining, from a first device by a second device, a message. The message decoding component 1240 may be configured as or otherwise support a means for decoding the message to generate a set of multiple shaped bits satisfying a target probability distribution associated with a block encoding scheme, the set of multiple shaped bits including a set of multiple information bits and a set of multiple shaping bits.

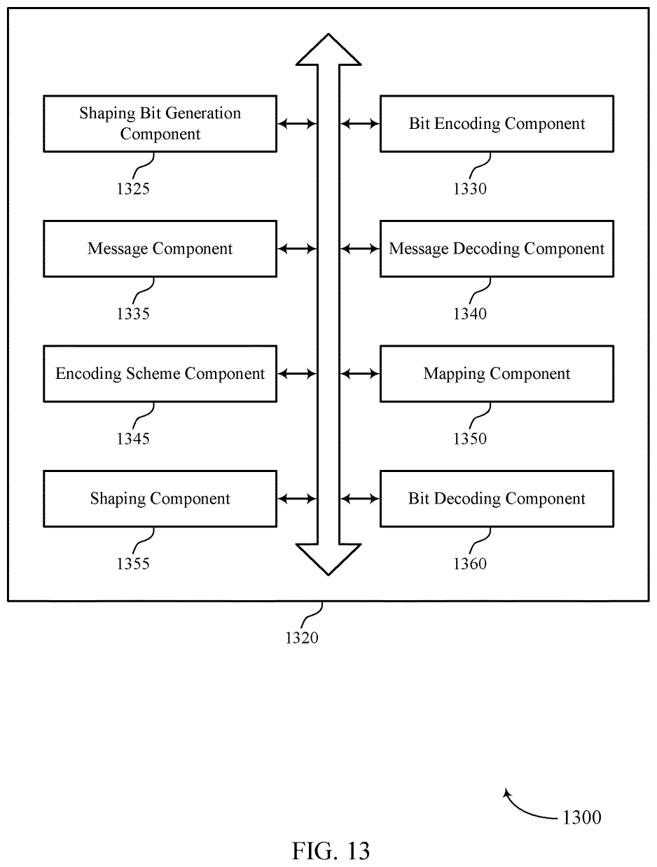

FIG. 13 illustrates a block diagram 1300 of an communications manager 1320 that supports probabilistic shaping based on block codes in accordance with one or more aspects of the present disclosure. The communications manager 1320 may be an example of aspects of an communications manager 1120, an communications manager 1220, or both, as described herein. The communications manager 1320, or various components thereof, may be an example of means for performing various aspects of probabilistic shaping based on block codes as described herein. For example, the communications manager 1320 may include a shaping bit generation component 1325, a bit encoding component 1330, a message component 1335, a message decoding component 1340, an encoding scheme component 1345, a mapping component 1350, a shaping component 1355, a bit decoding component 1360, or any combination thereof. Each of these components may communicate, directly or indirectly, with one another (e.g., via one or more buses).

The communications manager 1320 may support wireless communications at a first device in accordance with examples as disclosed herein. The shaping bit generation component 1325 may be configured as or otherwise support a means for generating, based on a set of multiple information bits, a set of multiple shaping bits associated with shaping the set of multiple information bits into a target probability distribution associated with a block encoding scheme. The bit encoding component 1330 may be configured as or otherwise support a means for encoding the set of multiple information bits and the set of multiple shaping bits according to the block encoding scheme to generate a set of multiple shaped bits satisfying the target probability distribution. The message component 1335 may be configured as or otherwise support a means for outputting a message that is based on the set of multiple shaped bits.

In some examples, the encoding scheme component 1345 may be configured as or otherwise support a means for determining the block encoding scheme associated with the target probability distribution for transmission of the message.

In some examples, the encoding scheme component 1345 may be configured as or otherwise support a means for communicating, with a second device, control signaling scheduling a transmission of the message and indicating the block encoding scheme, where determining the block encoding scheme is based on communicating the control signaling.

In some examples, the encoding scheme component 1345 may be configured as or otherwise support a means for communicating the control signaling indicating the target probability distribution for the message.

In some examples, the encoding scheme component 1345 may be configured as or otherwise support a means for communicating the control signaling indicating the message is generated using a channel coding scheme and the block encoding scheme.

In some examples, the encoding scheme component 1345 may be configured as or otherwise support a means for determining that the block encoding scheme is one of a polar coding scheme, a low-density generator matrix coding scheme, a convolution coding scheme, a turbo coding scheme, a Reed Muller coding scheme, an algebraic coding scheme, or any combination thereof.

In some examples, the encoding scheme component 1345 may be configured as or otherwise support a means for communicating control signaling indicating the block encoding scheme, the determining based on the control signaling.

In some examples, the mapping component 1350 may be configured as or otherwise support a means for determining a mapping of the set of multiple information bits to a set of multiple frozen bit locations and the set of multiple shaping bits to a set of multiple information bit locations, where the message is based on the mapping.

In some examples, the mapping component 1350 may be configured as or otherwise support a means for communicating control signaling indicating the mapping, the determining based on communicating the control signaling.

In some examples, the shaping bit generation component 1325 may be configured as or otherwise support a means for calculating a set of LLR values based on the target probability distribution. In some examples, the shaping bit generation component 1325 may be configured as or otherwise support a means for decoding the set of LLR values according to a decoding operation associated with the block encoding scheme to generate the set of multiple shaping bits.

In some examples, a set of multiple information bits are mapped to a set of multiple frozen bit locations of the block encoding scheme. In some examples, the set of multiple shaping bits are based on the set of decoded LLR values.

In some examples, the shaping bit generation component 1325 may be configured as or otherwise support a means for mapping a second set of multiple information bits and at least one candidate shaped bit to a modulation symbol. In some examples, the shaping bit generation component 1325 may be configured as or otherwise support a means for determining a conditional distribution based on the target probability distribution. In some examples, the shaping bit generation component 1325 may be configured as or otherwise support a means for determining a LLR value for the at least one candidate shaped bit based on the second set of multiple information bits and the conditional distribution associated with the modulation symbol, where calculating the set of LLR values is based on determining the LLR value for the at least one candidate shaped bit.

In some examples, the second set of multiple information bits is independently distributed from distribution of the set of multiple shaped bits according to the encoding.

In some examples, the shaping bit generation component 1325 may be configured as or otherwise support a means for shaping the second set of multiple information bits according to the encoding.

In some examples, the shaping component 1355 may be configured as or otherwise support a means for generating the set of multiple shaped bits using a joint decoder for the block encoding scheme and a channel encoding scheme based at least in part on the target probability distribution associated with the block encoding scheme and a second target probability distribution associated with the channel encoding scheme. In some examples, the shaping component 1355 may be configured as or otherwise support a means for applying a channel encoding scheme to the set of multiple shaped bits including the set of multiple information bits and the set of multiple shaping bits to generate a set of multiple parity bits.

In some examples, the shaping component 1355 may be configured as or otherwise support a means for calculating a first set of LLR values for the block encoding scheme based on the target probability distribution. In some examples, the shaping component 1355 may be configured as or otherwise support a means for calculating a second set of LLR values for the channel encoding scheme for the decoder associated with the channel encoding scheme, the second set of LLR values based on the second target probability distribution corresponding to the set of multiple parity bits, where shaping of the set of multiple shaped bits is based on the first set of LLR values and the second set of LLR values.

Additionally, or alternatively, the communications manager 1320 may support wireless communications in accordance with examples as disclosed herein. In some examples, the message component 1335 may be configured as or otherwise support a means for obtaining, from a first device by a second device, a message. The message decoding component 1340 may be configured as or otherwise support a means for decoding the message to generate a set of multiple shaped bits satisfying a target probability distribution associated with a block encoding scheme, the set of multiple shaped bits including a set of multiple information bits and a set of multiple shaping bits.

In some examples, the encoding scheme component 1345 may be configured as or otherwise support a means for determining the block encoding scheme associated with the target probability distribution for reception of the message.

In some examples, the encoding scheme component 1345 may be configured as or otherwise support a means for communicating, with the first device, control signaling scheduling a transmission of the message and indicating the block encoding scheme, where determining the block encoding scheme is based on communicating the control signaling.

In some examples, the encoding scheme component 1345 may be configured as or otherwise support a means for communicating the control signaling indicating the target probability distribution for the message.

In some examples, the encoding scheme component 1345 may be configured as or otherwise support a means for communicating the control signaling indicating the message is generated using a channel coding scheme and the block encoding scheme.

In some examples, the encoding scheme component 1345 may be configured as or otherwise support a means for determining that the block encoding scheme is one of a polar coding scheme, a low-density generator matrix coding scheme, a convolution coding scheme, a turbo coding scheme, a Reed Muller coding scheme, an algebraic coding scheme, or any combination thereof.

In some examples, the encoding scheme component 1345 may be configured as or otherwise support a means for communicating control signaling indicating the block encoding scheme, the determining based on the control signaling.

In some examples, the mapping component 1350 may be configured as or otherwise support a means for determining a mapping of the set of multiple information bits to a set of multiple frozen bit locations and the set of multiple shaping bits to a set of multiple information bits, where decoding the message is based on the mapping.

In some examples, the mapping component 1350 may be configured as or otherwise support a means for communicating control signaling indicating the block encoding scheme, the determining based on the control signaling.

In some examples, a second set of multiple information bits are independently distributed from a distribution of the set of multiple shaped bits according to the block encoding scheme.

In some examples, the bit decoding component 1360 may be configured as or otherwise support a means for jointly decoding the set of multiple shaped bits including the set of multiple information bits and the second set of multiple information bits according to a forward error correction decoder associated with a channel encoding scheme and the block encoding scheme, the set of multiple shaped bits including a set of multiple parity bits associated with the channel encoding scheme.

FIG. 14 illustrates a diagram of a system 1400 including a device 1405 that supports probabilistic shaping based on block codes in accordance with one or more aspects of the present disclosure. The device 1405 may be an example of or include the components of a device 1105, a device 1205, or any transmitting or receiving device as described herein. The device 1405 may be an example of a network entity 105, or a UE 115. The device 1405 may include components for bi-directional voice and data communications including components for transmitting and receiving communications, such as an communications manager 1420, an I/O controller 1410, a database controller 1415, a memory 1425, a processor 1430, and a database 1435. These components may be in electronic communication or otherwise coupled (e.g., operatively, communicatively, functionally, electronically, electrically) via one or more buses (e.g., a bus 1440).

The I/O controller 1410 may manage input signals 1445 and output signals 1450 for the device 1405. The I/O controller 1410 may also manage peripherals not integrated into the device 1405. In some cases, the I/O controller 1410 may represent a physical connection or port to an external peripheral. In some cases, the I/O controller 1410 may utilize an operating system such as iOS®, ANDROID®, MS-DOS®, MS-WINDOWS®, OS/2®, UNIX®, LINUX®, or another known operating system. Additionally or alternatively, the I/O controller 1410 may represent or interact with a modem, a keyboard, a mouse, a touchscreen, or a similar device. In some cases, the I/O controller 1410 may be implemented as part of a processor. In some examples, a user may interact with the device 1405 via the I/O controller 1410 or via hardware components controlled by the I/O controller 1410.

The database controller 1415 may manage data storage and processing in a database 1435. The database 1435 may be external to the device 1405, temporarily or permanently connected to the device 1405, or a data storage component of the device 1405. In some cases, a user may interact with the database controller 1415. In some other cases, the database controller 1415 may operate automatically without user interaction. The database 1435 may be an example of a persistent data store, a single database, a distributed database, multiple distributed databases, a database management system, or an emergency backup database.

Memory 1425 may include random-access memory (RAM) and ROM. The memory 1425 may store computer-readable, computer-executable software including instructions that, when executed, cause the processor to perform various functions described herein. In some cases, the memory 1425 may contain, among other things, a BIOS which may control basic hardware or software operation such as the interaction with peripheral components or devices.

The processor 1430 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 1430 may be configured to operate a memory array using a memory controller. In some other cases, a memory controller may be integrated into the processor 1430. The processor 1430 may be configured to execute computer-readable instructions stored in memory 1425 to perform various functions (e.g., functions or tasks supporting probabilistic shaping based on block codes).

The communications manager 1420 may support wireless communications at a first device in accordance with examples as disclosed herein. For example, the communications manager 1420 may be configured as or otherwise support a means for generating, based on a set of multiple information bits, a set of multiple shaping bits associated with shaping the set of multiple information bits into a target probability distribution associated with a block encoding scheme. The communications manager 1420 may be configured as or otherwise support a means for encoding the set of multiple information bits and the set of multiple shaping bits according to the block encoding scheme to generate a set of multiple shaped bits satisfying the target probability distribution. The communications manager 1420 may be configured as or otherwise support a means for outputting a message that is based on the set of multiple shaped bits.

Additionally, or alternatively, the communications manager 1420 may support wireless communications in accordance with examples as disclosed herein. For example, the communications manager 1420 may be configured as or otherwise support a means for obtaining, from a first device by a second device, a message. The communications manager 1420 may be configured as or otherwise support a means for decoding the message to generate a set of multiple shaped bits satisfying a target probability distribution associated with a block encoding scheme, the set of multiple shaped bits including a set of multiple information bits and a set of multiple shaping bits.

By including or configuring the communications manager 1420 in accordance with examples as described herein, the device 1405 may support techniques for shaping and transmitting information bits and shaping bits, resulting in reduced processing on the receiver side, decreased signaling overhead, reduced system latency, more efficient utilization of communication resources, improved reliability of wireless signaling, and improved user experience.

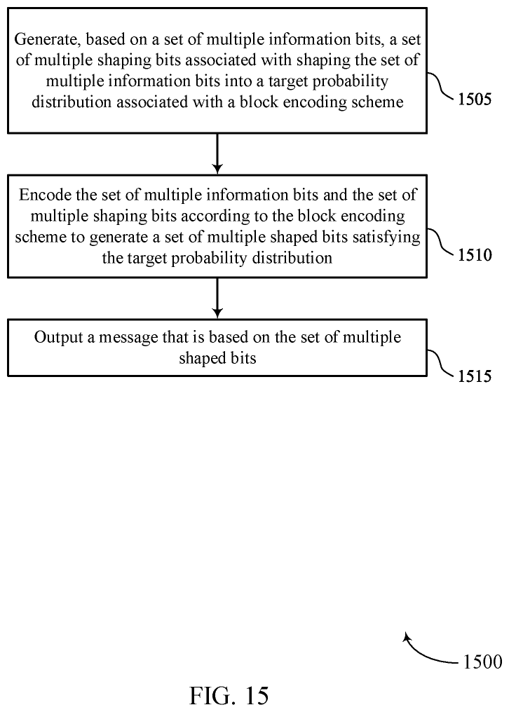

FIG. 15 illustrates a flowchart showing a method 1500 that supports probabilistic shaping based on block codes in accordance with one or more aspects of the present disclosure. The operations of the method 1500 may be implemented by a Generic Device or its components as described herein. For example, the operations of the method 1500 may be performed by a Generic Device as described with reference to FIGS. 1 through 14. In some examples, a Generic Device may execute a set of instructions to control the functional elements of the Generic Device to perform the described functions. Additionally, or alternatively, the Generic Device may perform aspects of the described functions using special-purpose hardware.

At 1505, the method may include generating, based on a set of multiple information bits, a set of multiple shaping bits associated with shaping the set of multiple information bits into a target probability distribution associated with a block encoding scheme. The operations of 1505 may be performed in accordance with examples as disclosed herein. In some examples, aspects of the operations of 1505 may be performed by a shaping bit generation component 1325 as described with reference to FIG. 13.

At 1510, the method may include encoding the set of multiple information bits and the set of multiple shaping bits according to the block encoding scheme to generate a set of multiple shaped bits satisfying the target probability distribution. The operations of 1510 may be performed in accordance with examples as disclosed herein. In some examples, aspects of the operations of 1510 may be performed by a bit encoding component 1330 as described with reference to FIG. 13.

At 1515, the method may include outputting a message that is based on the set of multiple shaped bits. The operations of 1515 may be performed in accordance with examples as disclosed herein. In some examples, aspects of the operations of 1515 may be performed by a message component 1335 as described with reference to FIG. 13.

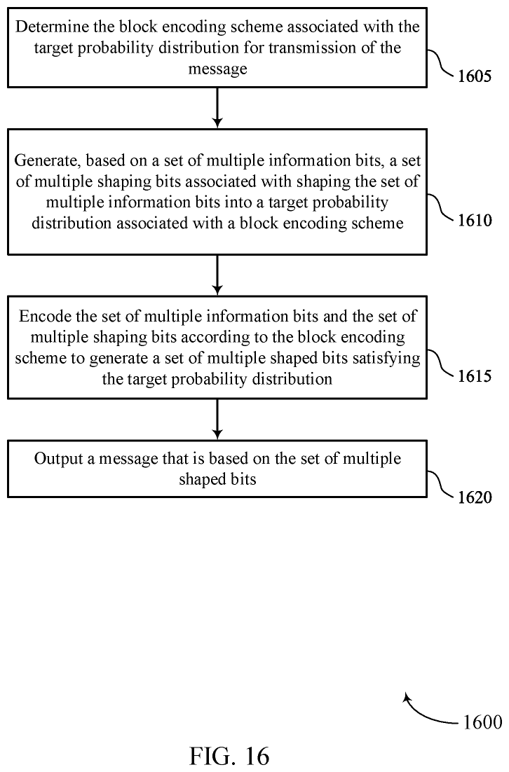

FIG. 16 illustrates a flowchart showing a method 1600 that supports probabilistic shaping based on block codes in accordance with one or more aspects of the present disclosure. The operations of the method 1600 may be implemented by a Generic Device or its components as described herein. For example, the operations of the method 1600 may be performed by a Generic Device as described with reference to FIGS. 1 through 14. In some examples, a Generic Device may execute a set of instructions to control the functional elements of the Generic Device to perform the described functions. Additionally, or alternatively, the Generic Device may perform aspects of the described functions using special-purpose hardware.

At 1605, the method may include determining the block encoding scheme associated with the target probability distribution for transmission of the message. The operations of 1605 may be performed in accordance with examples as disclosed herein. In some examples, aspects of the operations of 1605 may be performed by an encoding scheme component 1345 as described with reference to FIG. 13.

At 1610, the method may include generating, based on a set of multiple information bits, a set of multiple shaping bits associated with shaping the set of multiple information bits into a target probability distribution associated with a block encoding scheme. The operations of 1610 may be performed in accordance with examples as disclosed herein. In some examples, aspects of the operations of 1610 may be performed by a shaping bit generation component 1325 as described with reference to FIG. 13.

At 1615, the method may include encoding the set of multiple information bits and the set of multiple shaping bits according to the block encoding scheme to generate a set of multiple shaped bits satisfying the target probability distribution. The operations of 1615 may be performed in accordance with examples as disclosed herein. In some examples, aspects of the operations of 1615 may be performed by a bit encoding component 1330 as described with reference to FIG. 13.

At 1620, the method may include outputting a message that is based on the set of multiple shaped bits. The operations of 1620 may be performed in accordance with examples as disclosed herein. In some examples, aspects of the operations of 1620 may be performed by a message component 1335 as described with reference to FIG. 13.

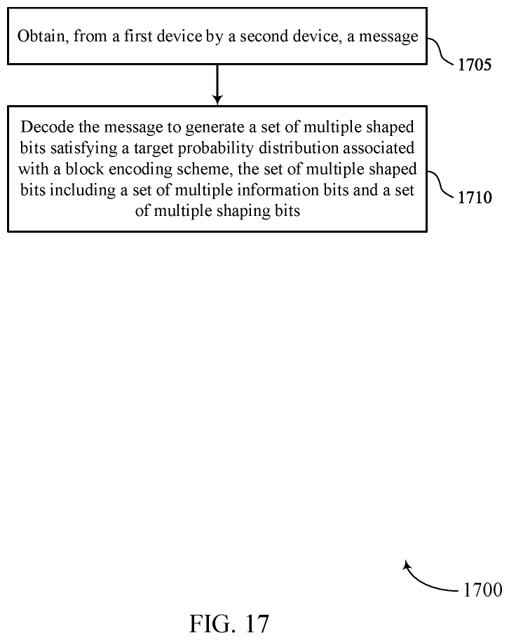

FIG. 17 illustrates a flowchart showing a method 1700 that supports probabilistic shaping based on block codes in accordance with one or more aspects of the present disclosure. The operations of the method 1700 may be implemented by a Generic Device or its components as described herein. For example, the operations of the method 1700 may be performed by a Generic Device as described with reference to FIGS. 1 through 14. In some examples, a Generic Device may execute a set of instructions to control the functional elements of the Generic Device to perform the described functions. Additionally, or alternatively, the Generic Device may perform aspects of the described functions using special-purpose hardware.

At 1705, the method may include obtaining, from a first device by a second device, a message. The operations of 1705 may be performed in accordance with examples as disclosed herein. In some examples, aspects of the operations of 1705 may be performed by a message component 1335 as described with reference to FIG. 13.

At 1710, the method may include decoding the message to generate a set of multiple shaped bits satisfying a target probability distribution associated with a block encoding scheme, the set of multiple shaped bits including a set of multiple information bits and a set of multiple shaping bits. The operations of 1710 may be performed in accordance with examples as disclosed herein. In some examples, aspects of the operations of 1710 may be performed by a message decoding component 1340 as described with reference to FIG. 13.

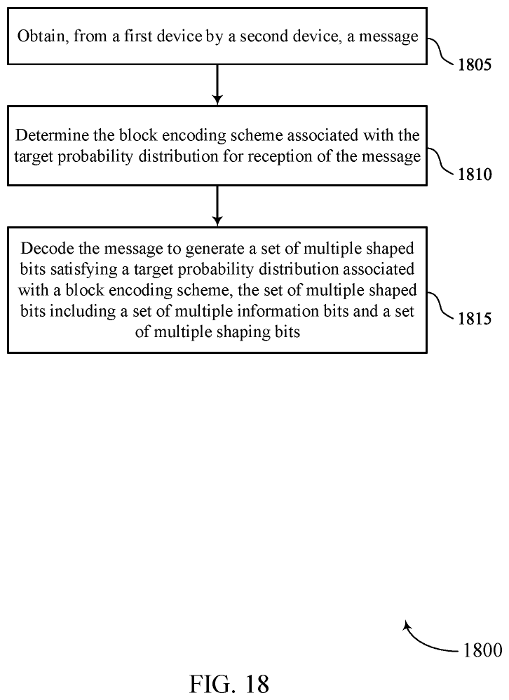

FIG. 18 illustrates a flowchart showing a method 1800 that supports probabilistic shaping based on block codes in accordance with one or more aspects of the present disclosure. The operations of the method 1800 may be implemented by a Generic Device or its components as described herein. For example, the operations of the method 1800 may be performed by a Generic Device as described with reference to FIGS. 1 through 14. In some examples, a Generic Device may execute a set of instructions to control the functional elements of the Generic Device to perform the described functions. Additionally, or alternatively, the Generic Device may perform aspects of the described functions using special-purpose hardware.

At 1805, the method may include obtaining, from a first device by a second device, a message. The operations of 1805 may be performed in accordance with examples as disclosed herein. In some examples, aspects of the operations of 1805 may be performed by a message component 1335 as described with reference to FIG. 13.

At 1810, the method may include determining the block encoding scheme associated with the target probability distribution for reception of the message. The operations of 1810 may be performed in accordance with examples as disclosed herein. In some examples, aspects of the operations of 1810 may be performed by an encoding scheme component 1345 as described with reference to FIG. 13.

At 1815, the method may include decoding the message to generate a set of multiple shaped bits satisfying a target probability distribution associated with a block encoding scheme, the set of multiple shaped bits including a set of multiple information bits and a set of multiple shaping bits. The operations of 1815 may be performed in accordance with examples as disclosed herein. In some examples, aspects of the operations of 1815 may be performed by a message decoding component 1340 as described with reference to FIG. 13.

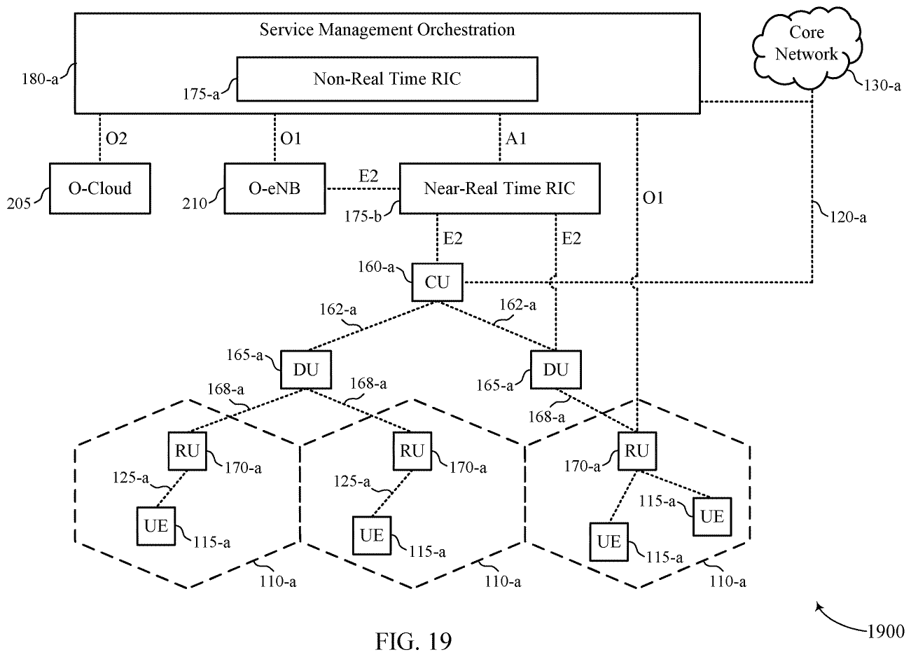

FIG. 19 illustrates an example of a network architecture 1900 (e.g., a disaggregated base station architecture, a disaggregated RAN architecture) that supports probabilistic shaping based on block codes in accordance with one or more aspects of the present disclosure. The network architecture 1900 may illustrate an example for implementing one or more aspects of the wireless communications system 100. The network architecture 1900 may include one or more CUs 160-a that may communicate directly with a core network 130-a via a backhaul communication link 120-a, or indirectly with the core network 130-a through one or more disaggregated network entities 105 (e.g., a Near-RT RIC 175-b via an E2 link, or a Non-RT RIC 175-a associated with an SMO 180-a (e.g., an SMO Framework), or both). A CU 160-a may communicate with one or more DUs 165-a via respective midhaul communication links 162-a (e.g., an F1 interface). The DUs 165-a may communicate with one or more RUs 170-a via respective fronthaul communication links 168-a. The RUs 170-a may be associated with respective coverage areas 110-a and may communicate with UEs 115-a via one or more communication links 125-a. In some implementations, a UE 115-a may be simultaneously served by multiple RUs 170-a.

Each of the network entities 105 of the network architecture 200 (e.g., CUs 160-a, DUs 165-a, RUs 170-a, Non-RT RICs 175-a, Near-RT RICs 175-b, SMOs 180-a, Open Clouds (O-Clouds) 205, Open eNBs (O-eNBs) 210) may include one or more interfaces or may be coupled with one or more interfaces configured to receive or transmit signals (e.g., data, information) via a wired or wireless transmission medium. Each network entity 105, or an associated processor (e.g., controller) providing instructions to an interface of the network entity 105, may be configured to communicate with one or more of the other network entities 105 via the transmission medium. For example, the network entities 105 may include a wired interface configured to receive or transmit signals over a wired transmission medium to one or more of the other network entities 105. Additionally, or alternatively, the network entities 105 may include a wireless interface, which may include a receiver, a transmitter, or transceiver (e.g., an RF transceiver) configured to receive or transmit signals, or both, over a wireless transmission medium to one or more of the other network entities 105.

In some examples, a CU 160-a may host one or more higher layer control functions. Such control functions may include RRC, PDCP, SDAP, or the like. Each control function may be implemented with an interface configured to communicate signals with other control functions hosted by the CU 160-a. A CU 160-a may be configured to handle user plane functionality (e.g., CU-UP), control plane functionality (e.g., CU-CP), or a combination thereof. In some examples, a CU 160-a may be logically split into one or more CU-UP units and one or more CU-CP units. A CU-UP unit may communicate bidirectionally with the CU-CP unit via an interface, such as an E1 interface when implemented in an O-RAN configuration. A CU 160-a may be implemented to communicate with a DU 165-a, as necessary, for network control and signaling.

A DU 165-a may correspond to a logical unit that includes one or more functions (e.g., base station functions, RAN functions) to control the operation of one or more RUs 170-a. In some examples, a DU 165-a may host, at least partially, one or more of an RLC layer, a MAC layer, and one or more aspects of a PHY layer (e.g., a high PHY layer, such as modules for FEC encoding and decoding, scrambling, modulation and demodulation, or the like) depending, at least in part, on a functional split, such as those defined by the 3rd Generation Partnership Project (3GPP). In some examples, a DU 165-a may further host one or more low PHY layers. Each layer may be implemented with an interface configured to communicate signals with other layers hosted by the DU 165-a, or with control functions hosted by a CU 160-a.

In some examples, lower-layer functionality may be implemented by one or more RUs 170-a. For example, an RU 170-a, controlled by a DU 165-a, may correspond to a logical node that hosts RF processing functions, or low-PHY layer functions (e.g., performing fast Fourier transform (FFT), inverse FFT (iFFT), digital beamforming, physical random access channel (PRACH) extraction and filtering, or the like), or both, based at least in part on the functional split, such as a lower-layer functional split. In such an architecture, an RU 170-a may be implemented to handle over the air (OTA) communication with one or more UEs 115-a. In some implementations, real-time and non-real-time aspects of control and user plane communication with the RU(s) 170-a may be controlled by the corresponding DU 165-a. In some examples, such a configuration may enable a DU 165-a and a CU 160-a to be implemented in a cloud-based RAN architecture, such as a vRAN architecture.

The SMO 180-a may be configured to support RAN deployment and provisioning of non-virtualized and virtualized network entities 105. For non-virtualized network entities 105, the SMO 180-a may be configured to support the deployment of dedicated physical resources for RAN coverage requirements which may be managed via an operations and maintenance interface (e.g., an O1 interface). For virtualized network entities 105, the SMO 180-a may be configured to interact with a cloud computing platform (e.g., an O-Cloud 205) to perform network entity life cycle management (e.g., to instantiate virtualized network entities 105) via a cloud computing platform interface (e.g., an O2 interface). Such virtualized network entities 105 can include, but are not limited to, CUs 160-a, DUs 165-a, RUs 170-a, and Near-RT RICs 175-b. In some implementations, the SMO 180-a may communicate with components configured in accordance with a 4G RAN (e.g., via an O1 interface). Additionally, or alternatively, in some implementations, the SMO 180-a may communicate directly with one or more RUs 170-a via an O1 interface. The SMO 180-a also may include a Non-RT RIC 175-a configured to support functionality of the SMO 180-a.

The Non-RT RIC 175-a may be configured to include a logical function that enables non-real-time control and optimization of RAN elements and resources, Artificial Intelligence (AI) or Machine Learning (ML) workflows including model training and updates, or policy-based guidance of applications/features in the Near-RT RIC 175-b. The Non-RT RIC 175-a may be coupled to or communicate with (e.g., via an A1 interface) the Near-RT RIC 175-b. The Near-RT RIC 175-b may be configured to include a logical function that enables near-real-time control and optimization of RAN elements and resources via data collection and actions over an interface (e.g., via an E2 interface) connecting one or more CUs 160-a, one or more DUs 165-a, or both, as well as an O-eNB 210, with the Near-RT RIC 175-b.

In some examples, to generate AI/ML models to be deployed in the Near-RT RIC 175-b, the Non-RT RIC 175-a may receive parameters or external enrichment information from external servers. Such information may be utilized by the Near-RT RIC 175-b and may be received at the SMO 180-a or the Non-RT RIC 175-a from non-network data sources or from network functions. In some examples, the Non-RT RIC 175-a or the Near-RT RIC 175-b may be configured to tune RAN behavior or performance. For example, the Non-RT RIC 175-a may monitor long-term trends and patterns for performance and employ AI or ML models to perform corrective actions through the SMO 180-a (e.g., reconfiguration via 01) or via generation of RAN management policies (e.g., A1 policies).

The following provides an overview of aspects of the present disclosure:

Aspect 1: A method for wireless communications at a first device, comprising: generating, based at least in part on a plurality of information bits, a plurality of shaping bits associated with shaping the plurality of information bits into a target probability distribution associated with a block encoding scheme; encoding the plurality of information bits and the plurality of shaping bits according to the block encoding scheme to generate a plurality of shaped bits satisfying the target probability distribution; and outputting a message that is based at least in part on the plurality of shaped bits.

Aspect 2: The method of aspect 1, further comprising: determining the block encoding scheme associated with the target probability distribution for transmission of the message.

Aspect 3: The method of aspect 2, further comprising: communicating, with a second device, control signaling scheduling a transmission of the message and indicating the block encoding scheme, wherein determining the block encoding scheme is based at least in part on communicating the control signaling.

Aspect 4: The method of aspect 3, the communicating comprising: communicating the control signaling indicating the target probability distribution for the message.

Aspect 5: The method of any of aspects 3 through 4, the communicating comprising: communicating the control signaling indicating the message is generated using a channel coding scheme and the block encoding scheme.

Aspect 6: The method of any of aspects 1 through 5, further comprising: determining that the block encoding scheme is one of a polar coding scheme, a low-density generator matrix coding scheme, a convolution coding scheme, a turbo coding scheme, a Reed Muller coding scheme, an algebraic coding scheme, or any combination thereof.

Aspect 7: The method of aspect 6, further comprising: communicating control signaling indicating the block encoding scheme, the determining based at least in part on the control signaling.

Aspect 8: The method of any of aspects 1 through 7, further comprising: determining a mapping of the plurality of information bits to a plurality of frozen bit locations and the plurality of shaping bits to a plurality of information bit locations, wherein the message is based at least in part on the mapping.

Aspect 9: The method of aspect 8, further comprising: communicating control signaling indicating the mapping, the determining based at least in part on communicating the control signaling.

Aspect 10: The method of any of aspects 1 through 9, the generating comprising: calculating a set of LLR values based at least in part on the target probability distribution; and decoding the set of LLR values according to a decoding operation associated with the block encoding scheme to generate the plurality of shaping bits.

Aspect 11: The method of aspect 10, wherein a plurality of information bits are mapped to a plurality of frozen bit locations of the block encoding scheme, and the plurality of shaping bits are based at least in part on the set of decoded LLR values.

Aspect 12: The method of any of aspects 10 through 11, the calculating comprising: mapping a second plurality of information bits and at least one candidate shaped bit to a modulation symbol; determining a conditional distribution based at least in part on the target probability distribution; and determining a LLR value for the at least one candidate shaped bit based at least in part on the second plurality of information bits and the conditional distribution associated with the modulation symbol, wherein calculating the set of LLR values is based at least in part on determining the LLR value for the at least one candidate shaped bit.

Aspect 13: The method of aspect 12, wherein the second plurality of information bits is independently distributed from distribution of the plurality of shaped bits according to the encoding.

Aspect 14: The method of any of aspects 12 through 13, further comprising: shaping the second plurality of information bits according to the encoding.

Aspect 15: The method of any of aspects 1 through 14, the encoding comprising: shaping the plurality of shaped bits using a joint decoder for the block encoding scheme and a channel encoding scheme; applying a channel encoding scheme to the plurality of shaped bits comprising the plurality of information bits and the plurality of shaping bits to generate a plurality of parity bits using a joint decoder of the block encoding scheme and the channel encoding scheme based at least in part on the target probability distribution associated with the block encoding scheme and a second target probability distribution associated with the channel encoding scheme.

Aspect 16: The method of aspect 15, further comprising: calculating a first set of LLR values for the block encoding scheme based at least in part on the target probability distribution; and calculating a second set of LLR values for the channel encoding scheme for the decoder associated with the channel encoding scheme, the second set of LLR values based at least in part on the second target probability distribution corresponding to the plurality of parity bits, wherein shaping of the plurality of shaped bits is based at least in part on the first set of LLR values and the second set of LLR values.

Aspect 17: A method for wireless communications, comprising: obtaining, from a first device by a second device, a message; and decoding the message to generate a plurality of shaped bits satisfying a target probability distribution associated with a block encoding scheme, the plurality of shaped bits comprising a plurality of information bits and a plurality of shaping bits.

Aspect 18: The method of aspect 17, further comprising: determining the block encoding scheme associated with the target probability distribution for reception of the message.

Aspect 19: The method of aspect 18, further comprising: communicating, with the first device, control signaling scheduling a transmission of the message and indicating the block encoding scheme, wherein determining the block encoding scheme is based at least in part on communicating the control signaling.

Aspect 20: The method of aspect 19, the communicating comprising: communicating the control signaling indicating the target probability distribution for the message.

Aspect 21: The method of any of aspects 19 through 20, the communicating comprising: communicating the control signaling indicating the message is generated using a channel coding scheme and the block encoding scheme.

Aspect 22: The method of any of aspects 17 through 21, further comprising: determining that the block encoding scheme is one of a polar coding scheme, a low-density generator matrix coding scheme, a convolution coding scheme, a turbo coding scheme, a Reed Muller coding scheme, an algebraic coding scheme, or any combination thereof.

Aspect 23: The method of aspect 22, further comprising: communicating control signaling indicating the block encoding scheme, the determining based at least in part on the control signaling.

Aspect 24: The method of any of aspects 17 through 23, further comprising: determining a mapping of the plurality of information bits to a plurality of frozen bit locations and the plurality of shaping bits to a plurality of information bits, wherein decoding the message is based at least in part on the mapping.

Aspect 25: The method of aspect 24, further comprising: communicating control signaling indicating the block encoding scheme, the determining based at least in part on the control signaling.

Aspect 26: The method of any of aspects 24 through 25, wherein a second plurality of information bits are independently distributed from a distribution of the plurality of shaped bits according to the block encoding scheme.

Aspect 27: The method of any of aspects 17 through 26, further comprising: jointly decoding the plurality of shaped bits comprising the plurality of information bits and the second plurality of information bits according to a forward error correction decoder associated with a channel encoding scheme and the block encoding scheme, the plurality of shaped bits comprising a plurality of parity bits associated with the channel encoding scheme.

Aspect 28: An apparatus for wireless communications at a first device, comprising a processor; memory coupled with the processor; and instructions stored in the memory and executable by the processor to cause the apparatus to perform a method of any of aspects 1 through 16.

Aspect 29: An apparatus for wireless communications at a first device, comprising at least one means for performing a method of any of aspects 1 through 16.

Aspect 30: A non-transitory computer-readable medium storing code for wireless communications at a first device, the code comprising instructions executable by a processor to perform a method of any of aspects 1 through 16.

Aspect 31: An apparatus for wireless communications, comprising a processor; memory coupled with the processor; and instructions stored in the memory and executable by the processor to cause the apparatus to perform a method of any of aspects 17 through 27.

Aspect 32: An apparatus for wireless communications, comprising at least one means for performing a method of any of aspects 17 through 27.

Aspect 33: A non-transitory computer-readable medium storing code for wireless communications, the code comprising instructions executable by a processor to perform a method of any of aspects 17 through 27.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

The term “determine” or “determining” encompasses a variety of actions and, therefore, “determining” can include calculating, computing, processing, deriving, investigating, looking up (such as via looking up in a table, a database or another data structure), ascertaining and the like. Also, “determining” can include receiving (e.g., receiving information), accessing (e.g., accessing data stored in memory) and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. An apparatus for wireless communications at a first device, comprising:
a processor; and
memory coupled with the processor, the processor configured to:
generate, based at least in part on a plurality of information bits, a plurality of shaping bits associated with shaping the plurality of information bits into a target probability distribution associated with a block encoding scheme;
encode the plurality of information bits and the plurality of shaping bits according to the block encoding scheme to generate a plurality of shaped bits satisfying the target probability distribution; and
output a message that is based at least in part on the plurality of shaped bits.

2. The apparatus of claim 1, wherein the processor is further configured to:
determine the block encoding scheme associated with the target probability distribution for transmission of the message.

3. The apparatus of claim 2, wherein the processor is further configured to:
communicate, with a second device, control signaling scheduling a transmission of the message and indicating the block encoding scheme, wherein the block encoding scheme is determined based at least in part on the control signaling.

4. (canceled)

5. (canceled)

6. The apparatus of claim 1, wherein the processor is further configured to:
determine that the block encoding scheme is one of a polar coding scheme, a low-density generator matrix coding scheme, a convolution coding scheme, a turbo coding scheme, a Reed Muller coding scheme, an algebraic coding scheme, or any combination thereof.

7. The apparatus of claim 6, wherein the processor is further configured to:
communicate control signaling indicating the block encoding scheme, wherein the block encoding scheme is determined based at least in part on the control signaling.

8. The apparatus of claim 1, wherein the processor is further configured to:
determine a mapping of the plurality of information bits to a plurality of frozen bit locations and the plurality of shaping bits to a plurality of information bit locations, wherein the message is based at least in part on the mapping.

9. The apparatus of claim 8, wherein the processor is further configured to:
communicate control signaling indicating the mapping, wherein the mapping is determined based at least in part on the control signaling.

10. The apparatus of claim 1, wherein the processor is further configured to:
calculate a set of log likelihood ratio values based at least in part on the target probability distribution; and
decode the set of log likelihood ratio values according to a decoding operation associated with the block encoding scheme to generate the plurality of shaping bits.

11. The apparatus of claim 10, wherein:
a plurality of information bits are mapped to a plurality of frozen bit locations of the block encoding scheme, and
the plurality of shaping bits are based at least in part on the set of decoded log likelihood ratio values.

12. The apparatus of claim 10, wherein the processor is further configured to:
map a second plurality of information bits and at least one candidate shaped bit to a modulation symbol;
determine a conditional distribution based at least in part on the target probability distribution; and
determine a log likelihood ratio value for the at least one candidate shaped bit based at least in part on the second plurality of information bits and the conditional distribution associated with the modulation symbol, wherein the set of log likelihood ratio values is calculated based at least in part on determining the log likelihood ratio value for the at least one candidate shaped bit.

13. (canceled)

14. (canceled)

15. The apparatus of claim 1, wherein the processor is further configured to:
generate the plurality of shaped bits using a joint decoder for the block encoding scheme and a channel encoding scheme based at least in part on the target probability distribution associated with the block encoding scheme and a second target probability distribution associated with the channel encoding scheme; and
apply a channel encoding scheme to the plurality of shaped bits comprising the plurality of information bits and the plurality of shaping bits to generate a plurality of parity bits

16. The apparatus of claim 15, wherein the processor is further configured to:
calculate a first set of log likelihood ratio values for the block encoding scheme based at least in part on the target probability distribution; and
calculate a second set of log likelihood ratio values for the channel encoding scheme for the decoder associated with the channel encoding scheme, the second set of log likelihood ratio values based at least in part on the second target probability distribution corresponding to the plurality of parity bits, wherein the plurality of shaped bits are shaped based at least in part on the first set of log likelihood ratio values and the second set of log likelihood ratio values.

17. (canceled)

18. An apparatus for wireless communications, comprising:
a processor; and
memory coupled with the processor, the processor configured to:
obtain, a message; and
decode the message to generate a plurality of shaped bits satisfying a target probability distribution associated with a block encoding scheme, the plurality of shaped bits comprising a plurality of information bits and a plurality of shaping bits.

19. The apparatus of claim 18, wherein the processor is further configured to:
determine the block encoding scheme associated with the target probability distribution for reception of the message.

20. The apparatus of claim 19, wherein the processor is further configured to:
communicate, with a first device, control signaling scheduling a transmission of the message and indicating the block encoding scheme, wherein the block encoding scheme is determined based at least in part on the control signaling.

21. (canceled)

22. (canceled)

23. The apparatus of claim 18, wherein the processor is further configured to:
determine that the block encoding scheme is one of a polar coding scheme, a low-density generator matrix coding scheme, a convolution coding scheme, a turbo coding scheme, a Reed Muller coding scheme, an algebraic coding scheme, or any combination thereof.

24. The apparatus of claim 23, wherein the processor is further configured to:
communicate control signaling indicating the block encoding scheme, wherein the block encoding scheme is determined based at least in part on the control signaling.

25. The apparatus of claim 18, wherein the processor is further configured to:
determine a mapping of the plurality of information bits to a plurality of frozen bit locations and the plurality of shaping bits to a plurality of information bits, wherein, to decode the message, the processor is further configured to decode the message based at least in part on the mapping.

26. The apparatus of claim 25, wherein the processor is further configured to:
communicate control signaling indicating the block encoding scheme, wherein the mapping is determined based at least in part on the control signaling.

27. The apparatus of claim 25, wherein a second plurality of information bits are independently distributed from a distribution of the plurality of shaped bits according to the block encoding scheme.

28.-30. (canceled)
